(19) United States
(12) Patent Application Publication
(10) Pub. No.: US 2026/0090368 A1
(43) Pub. Date: Mar. 26, 2026

(54) SEMICONDUCTOR MEMORY DEVICE

(71) Applicant: Samsung Electronics Co., Ltd., Suwon-si (KR)

(72) Inventors: Siwan KIM, Suwon-si (KR); Seung Hyeon YUN, Suwon-si (KR); Bumkyu KANG, Suwon-si (KR); Jiyoung KIM, Suwon-si (KR); Sehyung LEE, Suwon-si (KR); Sehoon LEE, Suwon-si (KR); Sukkang SUNG, Suwon-si (KR)

(73) Assignee: Samsung Electronics Co., Ltd., Suwon-si (KR)

(21) Appl. No.: 19/219,318

(22) Filed: May 27, 2025

(30) Foreign Application Priority Data
Sep. 24, 2024 (KR) 10-2024-0129415

(51) Int. Cl. H01L 23/522; H10B 43/10; H10B 43/27; H10B 43/35

(52) U.S. Cl. CPC H10W 20/496; H10B 43/10; H10B 43/27; H10B 43/35

(57) ABSTRACT

A semiconductor memory device may include a mold structure including a plurality of mold stacks, the plurality of mold stacks each including a plurality of gate electrodes stacked in a first direction, a first surface of the mold structure being opposite a second surface of the mold structure in the first direction; a capacitor structure penetrating at least one of the mold stacks in the first direction from the first surface of the mold structure; a cap filling insulation film penetrating the at least one of the mold stacks in the first direction from the second surface of the mold structure, and the cap filling insulation film being connected to the capacitor structure in the first direction; and a channel structure penetrating the mold structure in the first direction. The capacitor structure and the cap filling insulation film may not overlap in a direction crossing the first direction.

### CROSS-REFERENCE TO RELATED APPLICATIONS

This application claims the benefit of Korean Patent Application No. 10-2024-0129415, filed on Sep. 24, 2024 in the Korean Intellectual Property Office, the disclosure of which is incorporated herein by reference in its entirety.

### BACKGROUND

### 1. Field

The present disclosure relates to a semiconductor memory device.

### 2. Description of the Related Art

As a semiconductor memory device may be required to store a large volume of data in an electronic system, research on methods for increasing data storage capacity of the semiconductor memory device may be conducted. As one of the methods for increasing the data storage capacity of the semiconductor memory device, a semiconductor memory device including three-dimensionally arranged memory cells instead of two-dimensionally arranged memory cells is proposed.

As an input/output speed of the semiconductor memory device is gradually increased, precisely controlling noise in a signal may be required. The input/output speed may be increased by removing the noise in the signal by using a high-capacity capacitor.

### SUMMARY

An aspect provides a semiconductor memory device with improved quality of an input/output signal.

However, aspects of example embodiments of the present disclosure are not limited to the aspects described above and other aspects may be clearly understood from the following example embodiments by those skilled in the art.

According to an embodiment, a semiconductor memory device may include a mold structure comprising a plurality of gate electrodes stacked in a first direction, the mold structure including a first mold portion and a second mold portion that are disposed in the first direction, the mold structure including a capacitor hole penetrating the mold structure in the first direction; a capacitor structure in the capacitor hole and penetrating a portion of the mold structure in the first direction, the capacitor structure including a dielectric film and an electrode film; and a cap filling insulation film in the capacitor hole, the cap filling insulation film penetrating at least a part of the mold structure in the first direction and overlapping the capacitor structure in the first direction. The capacitor hole may include a first hole portion in the first mold portion and a second hole portion in the second mold portion. The first hole portion may not penetrate the second mold portion. The second hole portion may be connected to the first hole portion and may not penetrate the second mold portion. The dielectric film may extend along the first hole portion and may not extend along the second hole portion.

According to an embodiment, a semiconductor memory device may include a mold structure including a plurality of mold stacks, the plurality of mold stacks each including a plurality of gate electrodes stacked in a first direction, a first surface of the mold structure being opposite a second surface of the mold structure in the first direction; a capacitor structure penetrating at least one of the mold stacks in the first direction from the first surface of the mold structure; a cap filling insulation film penetrating the at least one of the mold stacks in the first direction from the second surface of the mold structure, and the cap filling insulation film being connected to the capacitor structure in the first direction; and a channel structure penetrating the mold structure in the first direction. The capacitor structure and the cap filling insulation film may not overlap in a direction crossing the first direction.

According to an embodiment, a semiconductor memory device may include a mold structure including a plurality gate electrodes stacked in a first direction, the mold structure including a first mold portion and a second mold portion that are disposed in the first direction; an inter-layer insulation film covering the mold structure; a capacitor structure penetrating the first mold portion in the first direction, the capacitor structure including a dielectric film and an electrode film; a cap filling insulation film penetrating the second mold portion in the first direction and overlapping the capacitor structure in the first direction; a contact plug penetrating the inter-layer insulation film, the contact plug being electrically connected to the capacitor structure; and an input/output pad on the inter-layer insulation film and connected to the contact plug. The capacitor structure may not overlap the second mold portion in a direction crossing the first direction. The cap filling insulation film may not overlap the first mold portion in the direction crossing the first direction.

Additional aspects of example embodiments will be set forth in part in the following description and drawings.

According to example embodiments, it is possible to improve quality of an input/output signal of a semiconductor memory device.

### BRIEF DESCRIPTION OF THE FIGURES

These and/or other aspects, features, and advantages of inventive concepts will become apparent and more readily appreciated from the following description of example embodiments, taken in conjunction with the accompanying drawings of which:

FIG. 1 is an example block diagram for describing a semiconductor memory device according to some example embodiments;

FIG. 2 is an example circuit diagram for describing a semiconductor memory device according to some example embodiments;

FIG. 3 is a schematic layout diagram for describing a semiconductor memory device according to some example embodiments;

FIG. 4 is an example diagram illustrating a cross section taken along line A-A′ of FIG. 3;

FIG. 5 is an example diagram illustrating an enlargement of part R1 of FIG. 4;

FIG. 6 is an example diagram illustrating an enlargement of part R2 of FIG. 4;

FIG. 7 is another example diagram illustrating an enlargement of part R2 of FIG. 4;

FIG. 8 is an example diagram illustrating a cross section taken along line B-B′ of FIG. 3;

FIG. 9 is another example diagram illustrating a cross section taken along line A-A′ of FIG. 3 for describing a semiconductor memory device according to some other example embodiments;

FIG. 10 is another example diagram illustrating a cross section taken along line A-A′ of FIG. 3 for describing a semiconductor memory device according to still some other example embodiments;

FIG. 11 is another example diagram illustrating a cross section taken along line A-A′ of FIG. 3 for describing a semiconductor memory device according to still some other example embodiments;

FIGS. 12 through 28 are diagrams illustrating operations for describing a method for manufacturing a semiconductor memory device according to some example embodiments;

FIG. 29 is an example diagram for describing an electronic system including a semiconductor memory device according to some example embodiments;

FIG. 30 is an example perspective diagram for describing an electronic system including a semiconductor memory device according to some example embodiments; and

FIG. 31 is an example diagram illustrating a cross section taken along line I-I of FIG. 30.

### DETAILED DESCRIPTION

Before example embodiments are described, terms or words used in the present disclosure and the accompanying claims are not to be limited to general definitions or dictionary definitions. The terms and words are to be construed under a principle that an inventor may appropriately define a concept of a term in order to describe inventive concepts in the best way. Thus, since example embodiments described in the present disclosure and configurations illustrated in the accompanying drawings are merely most desirable example embodiments and do not represent all of the technical spirit of the present disclosure, it should be understood that various equivalents and modifications that may replace the example embodiments and configurations may be present at the time of filing the application of the present disclosure.

In the following descriptions, terms in a singular form include terms in a plural form unless an apparently and contextually conflicting description is present. Terms such as “including” or “comprising” is to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

In the following descriptions, terms in a singular form include terms in a plural form unless an apparently and contextually conflicting description is present. Terms including an ordinal number such as “first” or “second” used in the present specification may be used to describe various elements. However, the elements may not be limited by the terms including the ordinal number. The terms may be used to contextually distinguish one element from another element in a part of the specification. Within a range of the technical spirit of the present disclosure, a first element may be referred to as a second element in another part of the specification, and reversely, the second element may be referred to as the first element in another part of the specification. Also, in the accompanying drawings, shapes, sizes, or the like of elements in the drawings may be exaggerated for clearer description.

In addition, it should be noted in advance that an expression such as an upper side, an upper portion, a lower side, a lower portion, a side surface, a front surface, or a rear surface is based on directions illustrated in the drawings and that the expression may be changed when a direction of a corresponding object is changed. Shapes, sizes, or the like of elements in the drawings may be exaggerated for clearer description. While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

Hereinafter, the example embodiments of the present disclosure will be described with reference to the drawings.

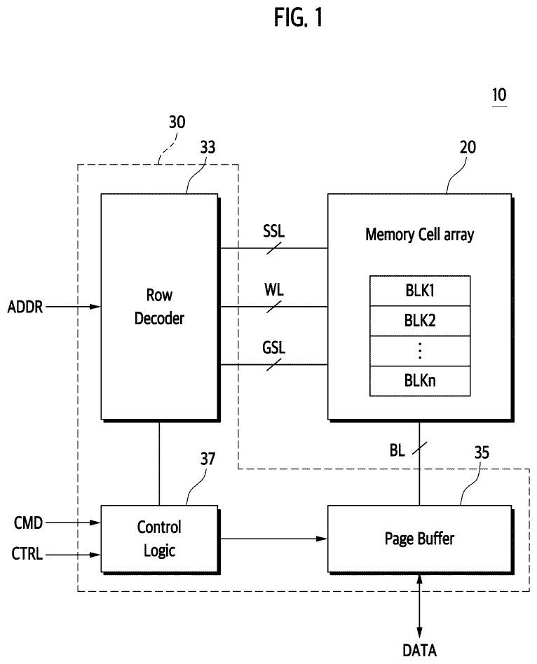

FIG. 1 is an example block diagram for describing a semiconductor memory device according to some example embodiments.

Referring to FIG. 1, a semiconductor memory device 10 according to some example embodiments may include a memory cell array 20 and a peripheral circuit 30.

According to some example embodiments, the memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 through a bit line BL, a word line WL, at least one string selection line SSL, and at least one ground selection line GSL. Specifically, the memory cell blocks BLK1 to BLKn may be connected to a row decoder 33 through the word line WL, the string selection line SSL, and the ground selection line GSL. In addition, the memory cell blocks BLK1 to BLKn may be connected to a page buffer 35 through the bit line BL.

According to some example embodiments, the peripheral circuit 30 may receive an address ADDR, a command CMD, and a control signal CTRL from an outside of the semiconductor memory device 10 and may transmit and receive data DATA to and from a device at the outside of the semiconductor memory device 10. The peripheral circuit 30 may include a control logic 37, the row decoder 33, and the page buffer 35. Although not illustrated, the peripheral circuit 30 may further include various sub-circuits such as a voltage generation circuit that generates various voltages required for an operation of the semiconductor memory device 10 and an error correction circuit for correcting an error in the data DATA which is read from the memory cell array 20.

According to some example embodiments, the control logic 37 may be connected to the row decoder 33, an input/output circuit, and the voltage generation circuit. The control logic 37 may control overall operations of the semiconductor memory device 10. The control logic 37 may generate, in response to the control signal CTRL, various internal control signals used in the semiconductor memory device 10. For example, when a memory operation such as a program operation or an erasure operation is performed, the control logic 37 may adjust a voltage level provided through the word line WL and the bit line BL.

According to some example embodiments, the row decoder 33 may select at least one from the plurality of memory cell blocks BLK1 to BLKn in response to the address ADDR and may select the word line WL, the string selection line SSL, and the ground selection line GSL of the at least one selected from the plurality of memory cell blocks BLK1 to BLKn. Also, the row decoder 33 may transfer a voltage for performing the memory operation to word lines WL of selected memory cell blocks BLK1 to BLKn.

According to some example embodiments, the page buffer 35 may be connected to the memory cell array 20 through the bit line BL. The page buffer 35 may operate as a writer driver or a sense amplifier. Specifically, when the program operation is performed, the page buffer 35 may operate as the writer driver to apply a voltage according to the data DATA to be stored in the memory cell array 20 to the bit line BL. Meanwhile, when a reading operation is performed, the page buffer 35 may operate as the sense amplifier to sense the data DATA which is stored in the memory cell array 20.

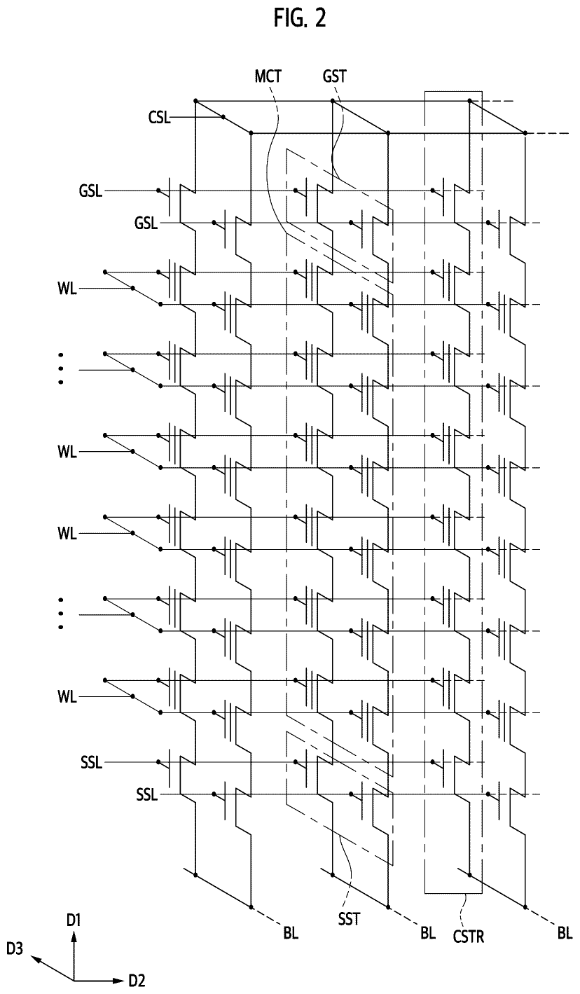

FIG. 2 is an example circuit diagram for describing a semiconductor memory device according to some example embodiments.

Referring to FIG. 2, a memory cell array (e.g., the memory cell array 20 of FIG. 1) of the semiconductor memory device according to some example embodiments may include a common source line CSL, a plurality of bit lines BL, and a plurality of cell strings CSTR.

According to some example embodiments, the plurality of bit lines Bl may be two-dimensionally arranged on a plane including a second direction D2 and a third direction D3. For example, each of the bit lines BL may be extended in the third direction D3, and the bit lines BL may be spaced apart from each other to be arranged in the second direction D2. The plurality of cell strings CSTR may be connected to each of the bit lines BL in parallel. The cell strings CSTR may be commonly connected to the common source line CSL. In other words, the plurality of cell strings CSTR may be disposed between the bit line BL and the common source line CSL. The plurality of cell strings CSTR may be extended in a first direction D1.

According to some example embodiments, each of the plurality of cell strings CSTR may include a ground selection transistor GST connected to the common source line CSL, a string selection transistor SST connected to the bit line BL, and a plurality of memory cell transistors MCT disposed between the ground selection transistor GST and string the selection transistor SST. Each of the memory cell transistors MCT may include a data storage element. The ground selection transistor GST, the string selection transistor SST, and the memory cell transistors MCT may be connected in series.

According to some example embodiments, the common source line CSL may be commonly connected to sources of ground selection transistors GST. In addition, the ground selection line GSL, a plurality of word lines WL, and the string selection line SSL may be disposed between the common source line GSL and the bit line WL. The ground selection line GSL may be used as a gate electrode of the ground selection transistor GST. The plurality of word lines WL may be used as gate electrodes of the memory cell transistors MCT. The string selection line SSL may be used as a gate electrode of the string selection transistor SST.

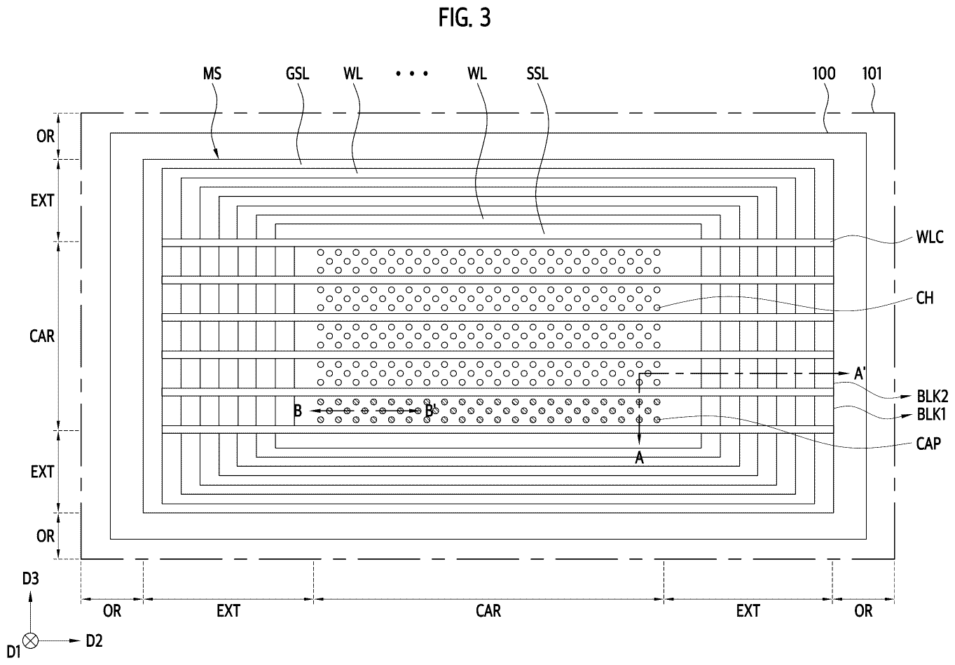

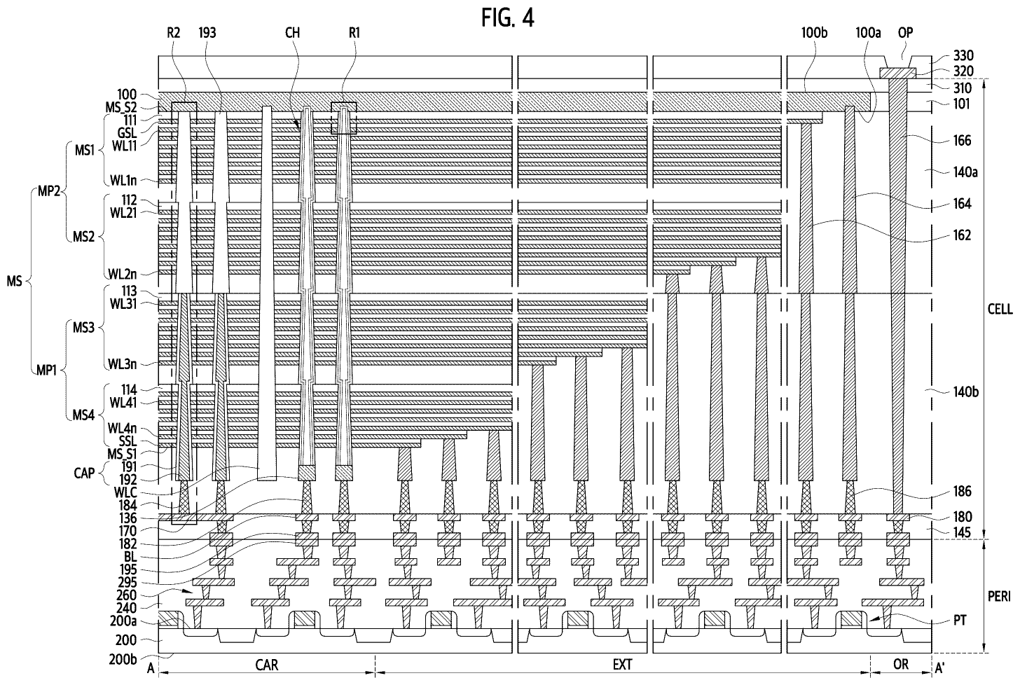

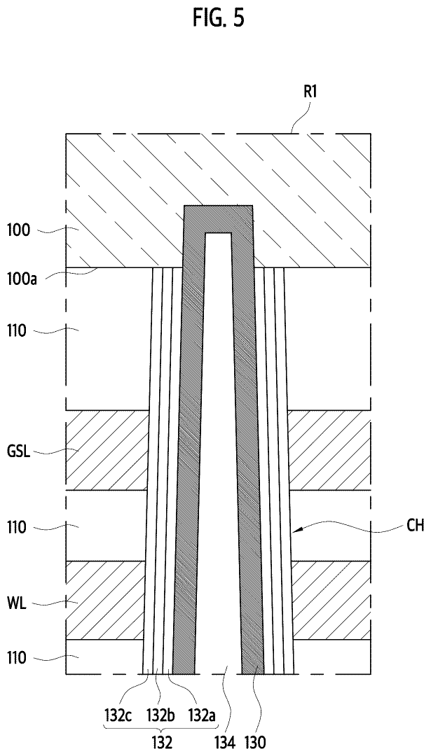

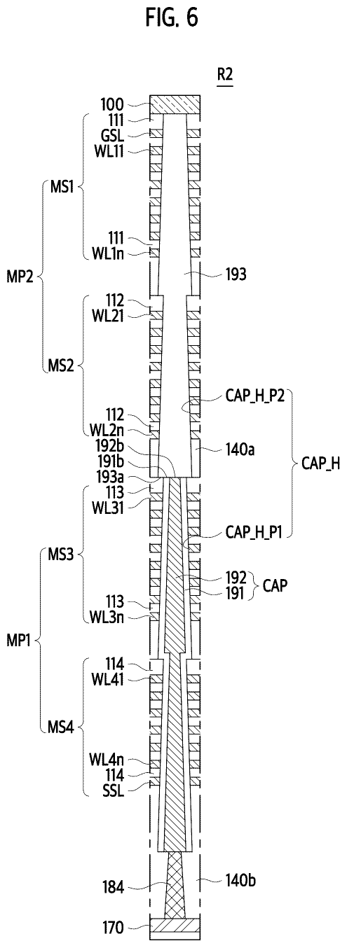

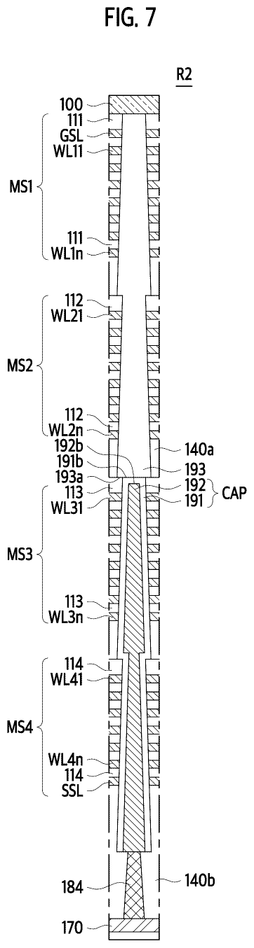

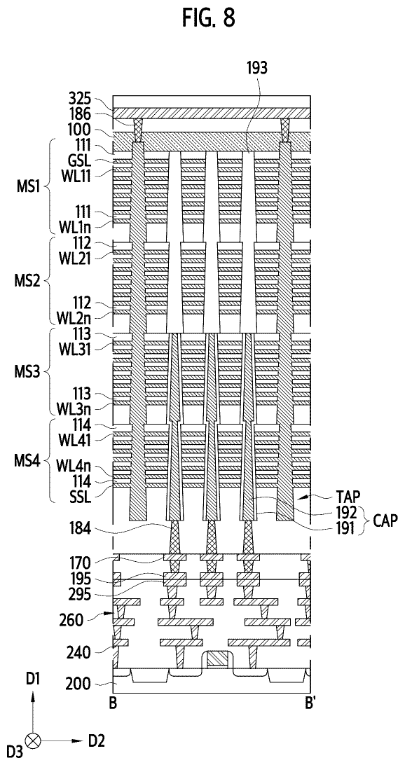

FIG. 3 is a schematic layout diagram for describing a semiconductor memory device according to some example embodiments. FIG. 4 is an example diagram illustrating a cross section taken along line A-A′ of FIG. 3. FIG. 5 is an example diagram illustrating an enlargement of part R1 of FIG. 4. FIG. 6 is an example diagram illustrating an enlargement of part R2 of FIG. 4. FIG. 7 is another example diagram illustrating an enlargement of part R2 of FIG. 4. FIG. 8 is an example diagram illustrating a cross section taken along line B-B′ of FIG. 3.

Referring to FIGS. 3 through 8, the semiconductor memory device according to some example embodiments may include a cell structure CELL and a peripheral circuit structure PERI.

According to some example embodiments, the cell structure CELL may include a cell substrate 100, an insulation substrate 101, a mold structure MS, a first inter-layer insulation film 140a, a second inter-layer insulation film 140b, a gate electrode cutting pattern WLC, a channel structure CH, the bit line BL, a capacitor structure CAP, a cap filling insulation film 193, a cell contact 162, a cell wiring structure 180, and an input/output pad 320.

According to some example embodiments, the cell substrate 100 may include, for example, a semiconductor substrate such as a silicon substrate, a germanium substrate, or a silicon-germanium substrate. Alternatively, the cell substrate 100 may include a silicon-on-insulator (SOI) substrate, a germanium-on-insulator (GOI) substrate, or the like.

According to some example embodiments, the cell substrate 100 may include an impurity. For example, the cell substrate 100 may include an n-type impurity (e.g., phosphorus (P), arsenic (As), or the like). However, it is merely an example. For example, the cell substrate 100 may also include a P-type impurity. The cell substrate 100 may include poly-silicon (poly-Si) doped with the N-type impurity. The cell substrate 100 may be provided as a common source line (e.g., the common source line CSL of FIG. 2) of the semiconductor memory device according to some example embodiments.

According to some example embodiments, the cell substrate 100 may include a cell array region CAR and an extended region EXT.

According to some example embodiments, a memory cell array (e.g., the memory cell array 20 of FIG. 1) including a plurality of memory cells may be formed in the cell array region CAR. For example, the channel structure CH, the bit line BL, a plurality of gate electrodes GSL, WL11 to WL1n, WL21 to 2n, WL31 to WL3n, WL41 to 4n, and SSL, and the like which will be described below may be disposed in the cell array region CAR. In the following description, a surface of the cell substrate 100 on which the memory cell array is disposed may be referred to as a first surface 100a of the cell substrate. The first surface 100a of the cell substrate may be a front side of the cell substrate 100. In contrast, a surface of the cell substrate 100 opposite to the first surface 100a of the cell substrate may be referred to as a second surface 100b of the cell substrate. The second surface 100b of the cell substrate may be a back side of the cell substrate 100.

According to some example embodiments, the gate electrode cutting pattern WLC may be extended in the first direction D1. The gate electrode cutting pattern WLC may penetrate the mold structure MS in the first direction D1. Specifically, the gate electrode cutting pattern WLC may be extended along a plane including the first direction D1 and the second direction D2. The gate electrode cutting pattern WLC may be extended from the cell substrate 100 in the first direction D1 to cut the plurality of gate electrodes GSL, WL11 to WL1n, WL21 to 2n, WL31 to WL3n, WL41 to 4n, and SSL. The gate electrode cutting pattern WLC may cut the plurality of gate electrodes GSL, WL11 to WL1n, WL21 to 2n, WL31 to WL3n, WL41 to 4n, and SSL along the plane including the first direction D1 and the second direction D2. For example, the gate electrode cutting pattern WLC may divide the mold structure MS into a first block BLK1 and a second block BLK2 by penetrating the mold structure MS. The gate electrode cutting pattern WLC may include an insulation material (e.g., at least one of silicon oxide, silicon nitride, and silicon oxynitride), but it is merely an example.

According to some example embodiments, the gate electrode cutting pattern WLC may be extended in the second direction D2. The gate electrode cutting pattern WLC may be extended across the cell array region CAR and the extended region EXT. For example, the gate electrode cutting pattern WLC may be extended across the cell array region CAR and the extended region EXT which is disposed to be adjacent to the cell array region CAR in the second direction D2.

According to some example embodiments, the gate electrode cutting pattern WLC may be spaced apart from another in the third direction D3. The gate electrode cutting pattern WLC may separate the mold structure MS into a plurality of blocks in the third direction D3. The plurality of blocks may be disposed in the third direction D3. The plurality of blocks may include the first block BLK1 and the second block BLK2. The gate electrode cutting pattern WLC may be disposed between the first block BLK1 and the second block BLK2. The gate electrode cutting pattern WLC may be disposed between two adjacent blocks. Each of the first block BLK1 and the second block BLK2 may be disposed between two gate electrode cutting patterns WLC adjacent in the third direction D3.

According to some example embodiments, the mold structure MS may include the first block BLK1 and the second block BLK2. The first block BLK1 and the second block BLK2 may be disposed in the third direction D3. In the third direction D3, the first block BLK1 may be disposed outward of the second block BLK2.

According to some example embodiments, the extended region EXT may be disposed around the cell array region CAR. For example, the extended region EXT may surround the cell array region CAR when viewed in a plan view. The plurality of gate electrodes GSL, WL11 to WL1n, WL21 to 2n, WL31 to WL3n, WL41 to 4n, and SSL which will be described below may be stacked in the extended region EXT in a form of stairs. However, it is merely an example. For example, in the extended region EXT, the plurality of gate electrodes GSL, WL11 to WL1n, WL21 to 2n, WL31 to WL3n, WL41 to 4n, and SSL may not be stacked in the form of stairs and each may be stacked on a plane including the second direction D2 and the third direction D3 while having an area equal to another.

According to some example embodiments, the insulation substrate 101 may be formed around the cell substrate 100. The insulation substrate 101 may form an insulation region around the cell substrate 100. The insulation substrate 101 may include, for example, at least one of silicon oxide, silicon nitride, silicon oxynitride, and silicon carbide, but it is merely an example.

According to some example embodiments, a lower surface of the insulation substrate 101 is only illustrated as being disposed on a plane common to the first surface 100a of the cell substrate, but it is merely an example. As another example, the lower surface of the insulation substrate 101 may be lower than the first surface 100a of the cell substrate.

According to some example embodiments, the cell substrate 100 and the insulation substrate 101 may further include an outer region OR. The outer region OR may be disposed at an outside of the cell array region CAR and the extended region EXT. For example, the outer region OR may surround the cell array region CAR and the extended region EXT when viewed in a plan view. A contact plug 166 that will be described below may be disposed in the outer region OR.

According to some example embodiments, the mold structure MS may be formed on the first surface 100a of the cell substrate. The mold structure MS may include the plurality of gate electrodes GSL, WL11 to WL1n, WL21 to 2n, WL31 to WL3n, WL41 to 4n, and SSL which is stacked on the cell substrate 100 and a plurality of mold insulation films 111, 112, 113, and 114. The plurality of gate electrodes GSL, WL11 to WL1n, WL21 to 2n, WL31 to WL3n, WL41 to 4n, and SSL and the plurality of mold insulation films 111, 112, 113, and 114 may be a layered structure extended in parallel with the first surface 100a of the cell substrate. The plurality of gate electrodes GSL, WL11 to WL1n, WL21 to 2n, WL31 to WL3n, WL41 to 4n, and SSL may be spaced apart from each other by the plurality of mold insulation films 111, 112, 113, and 114 and stacked on the first surface 100a of the cell substrate. The plurality of gate electrodes GSL, WL11 to WL1n, WL21 to 2n, WL31 to WL3n, WL41 to 4n, and SSL is illustrated as including only one ground selection line GSL and one string selection line SSL, but it is merely an example. The plurality of gate electrode GSL, WL11 to WL1n, WL21 to 2n, WL31 to WL3n, WL41 to 4n, and SSL may also include two or more ground selection lines and two or more string selection lines.

According to some example embodiments, the mold structure MS may include a plurality of mold stacks MS1, MS2, MS3, and MS4 stacked in sequential order on the first surface 100a of the cell substrate. For example, the mold structure MS may include a first mold stack MS1, a second mold stack MS2, a third mold stack MS3, and a fourth mold stack MS4.

According to some example embodiments, the first mold stack MS1 may include first gate electrodes GSL and WL1 to WL1n and a plurality of first mold insulation films 111 that are alternately stacked on the cell substrate 100. In some example embodiments, the first gate electrodes GSL and WL1 to WL1n may include the ground selection line GSL and first word lines WL1 to WL1n which are stacked in sequential order on the cell substrate 100. The second mold stack MS2 may include second gate electrodes WL21 to WL2n and a plurality of second mold insulation films 112 that are alternately stacked on the first mold stack MS1. In some example embodiments, the second gate electrodes WL21 to WL2n may include second word lines WL21 to WL2n stacked in sequential order on the first mold stack MS1. The third mold stack MS3 may include third gate electrodes WL31 to WL3n and a plurality of third mold insulation films 113 that are alternately stacked on the second mold stack MS2. In some example embodiments, the third gate electrodes WL31 to WL3n may include third word lines WL31 to WL3n stacked in sequential order on the second mold stack MS2. The fourth mold stack MS4 may include fourth gate electrodes WL41 to WL4n and SSL and a plurality of fourth mold insulation films 114 that are alternately stacked on the third mold stack MS3. In some example embodiments, the fourth gate electrodes WL41 to WL4n and SSL may include fourth word lines WL41 to WL4n and the string selection line SSL which are stacked in sequential order on the third mold stack MS3.

According to some example embodiments, each of the plurality of gate electrodes GSL, WL11 to WL1n, WL21 to 2n, WL31 to WL3n, WL41 to 4n, and SSL may include a conductive material (e.g., a semiconductor material such as a metal including tungsten (W), cobalt (Co), nickel (Ni), or the like or silicone), but it is merely an example.

According to some example embodiments, each of the plurality of mold insulation films 111, 112, 113, and 114 may include an insulation material. For example, the plurality of mold insulation films 111, 112, 113, and 114 may include at least one of silicon oxide, silicon nitride, and silicon oxynitride, but it is merely an example.

According to some example embodiments, the mold structure MS may include a first mold portion MP1 and a second mold portion MP2. The first mold portion MP1 and the second mold portion MP2 may be disposed in the first direction D1. The first mold portion MP1 may be a portion of the mold structure MS which is penetrated by the capacitor structure CAP. For example, the first mold portion MP1 may include the third mold stack MS3 and the fourth mold stack MS4. The second mold portion MP2 may be a portion of the mold structure MS which is penetrated by a cap filling insulation film 193. For example, the second mold portion MP2 may include the first mold stack MS1 and the second mold stack MS2.

According to some example embodiments, the mold structure MS may include a first surface MS_S1 and a second surface MS_S2 disposed opposite to each other in the first direction D1. The first surface MS_S1 may face the peripheral circuit structure PERI. The second surface MS_S2 may be disposed opposite to the first surface MS_S1 in the first direction D1. However, it is merely an example. For example, the second surface MS_S2 may face the peripheral circuit structure PERI, and the first surface MS_S1 may be a surface disposed opposite to the second surface MS_S2 in the first direction D1.

According to some example embodiments, the first inter-layer insulation film 140a may be formed on the insulation substrate 101 and/or the first surface 100a of the cell substrate to cover at least a portion of the mold structure MS. For example, the first inter-layer insulation film 140a may cover the first mold stack MS1 and the second mold stack MS2. The first inter-layer insulation film 140a may include, for example, at least one of silicon oxide, silicon oxynitride, and a low-permittivity (low-k) material having permittivity lower than that of silicon oxide, but it is merely an example.

According to some example embodiments, the second inter-layer insulation film 140b may cover at least a portion of the mold structure MS below the insulation substrate 101 and/or the first surface 100a of the cell substrate. For example, the second inter-layer insulation film 140b may cover the third mold stack MS3 and the fourth mold stack MS4. The first inter-layer insulation film 140a may include, for example, at least one of silicon oxide, silicon oxynitride, and the low-permittivity (low-k) material having the permittivity lower than that of silicon oxide, but it is merely an example.

According to some example embodiments, the channel structure CH may be formed in the mold structure MS in the cell array region CAR. The channel structure CH may be extended in the first direction D1 which is perpendicular to the first surface 100a of the cell substrate to penetrate the mold structure MS. The channel structure CH may be disposed to the second block BLK2. The channel structure CH may penetrate the mold structure MS in the second block BLK2 in the first direction D1. For example, the channel structure CH may have a pillar shape (e.g., a cylindrical shape) extended in the first direction D1. Accordingly, the channel structure CH may cross each of the plurality of gate electrodes GSL, WL11 to WL1n, WL21 to 2n, WL31 to WL3n, WL41 to 4n, and SSL.

According to some example embodiments, the channel structure CH may have a bent portion in the mold structure MS. The mold structure CH may have bent portions between the first mold stack MS1, the second mold stack MS2, the third mold stack MS3, and the fourth mold stack MS4. The mold structure CH may have a bent portion at a boundary between the first mold stack MS1 and the second mold stack MS2. The mold structure CH may have a step at the boundary between the first mold stack MS1 and the second mold stack MS2. The mold structure CH may have a bent portion at a boundary between the second mold stack MS2 and the third mold stack MS3. The mold structure CH may have a step at the boundary between the second mold stack MS2 and the third mold stack MS3. The mold structure CH may have a bent portion at a boundary between the third mold stack MS3 and the fourth mold stack MS4. The mold structure CH may have a step at the boundary between the third mold stack MS3 and the fourth mold stack MS4.

According to some example embodiments, the channel structure CH may be arranged in a zigzag form. For example, channel structures CH may be staggered in the second direction D2 and the third direction D3 which are parallel to the first surface 100a of the cell substrate. A plurality of channel structures CH arranged in the zigzag form may further improve a degree of integration of the semiconductor memory device. According to some example embodiments, the plurality of channel structures CH may be arranged in a honeycomb form.

According to some example embodiments, the channel structure CH may include a semiconductor pattern 130 and an information storage film 132.

According to some example embodiments, the semiconductor pattern 130 may be extended in the first direction D1 to cross the plurality of gate electrodes GSL, WL11 to WL1n, WL21 to 2n, WL31 to WL3n, WL41 to 4n, and SSL. Only the semiconductor pattern 130 which has a shape of a cup is illustrated, but it is merely an example. For example, the semiconductor pattern 130 may have various shapes such as a cylindrical shape, a quadrangular container shape, or a filler shape of which an inside is filled. The semiconductor pattern 130 may include, for example, a semiconductor material such as monocrystalline silicon, polycrystalline silicon, an organic semiconductor material, and a carbon nanostructure, but it is merely an example.

According to some example embodiments, the semiconductor pattern 130 may be connected to the cell substrate 100. For example, an end (e.g., an upper end) of the semiconductor pattern 130 may be exposed from the information storage film 132 to be connected to the cell substrate 100. According to some example embodiments, the semiconductor pattern 130 may penetrate the first surface 100a of the cell substrate 100. For example, the end (e.g., the upper end) of the semiconductor pattern 130 may protrude toward the cell substrate 100 further than the information storage film 132. The semiconductor pattern 130 may improve contact resistance by increasing an area in contact with the cell substrate 100.

According to some example embodiments, the information storage film 132 may be interposed between the semiconductor pattern 130 and each of the plurality of gate electrodes GSL, WL11 to WL1n, WL21 to 2n, WL31 to WL3n, WL41 to 4n, and SSL. For example, the information storage film 132 may be extended along an outer side surface of the semiconductor pattern 130. The information storage film 132 may include, for example, silicon oxide, silicon nitride, silicon oxynitride, and a high-permittivity material having permittivity higher than that of silicon oxide. The high-permittivity material may include, for example, at least one of aluminum oxide, hafnium oxide, lanthanum oxide, tantalum oxide, titanium oxide, lanthanum hafnium oxide, lanthanum aluminum oxide, dysprosium scandium oxide and a combination thereof.

According to some example embodiments, the information storage film 132 may be formed as a multilayered film. For example, as illustrated in FIG. 5, the information storage film 132 may include a tunnel insulation film 132a, an electric charge storing film 132b, and a blocking insulation film 132c that are stacked on the outer side surface of the semiconductor pattern 130 in sequential order.

According to some example embodiments, the tunnel insulation film 132a may include, for example, silicon oxide or the high-permittivity material having the permittivity higher than that of silicon oxide (e.g., aluminum oxide (Al₂O₃) or hafnium oxide (HfO2)). The electric charge storing film 132b may include, for example, silicon nitride. According to some example embodiments, the blocking insulation film 132c may include, for example, silicon oxide or the high-permittivity material having the permittivity higher than that of silicon oxide (e.g., aluminum oxide (Al₂O₃) or hafnium oxide (HfO₂)).

According to some example embodiments, the channel structure CH may further include a filling insulation film 134. The filling insulation film 134 may be formed to fill an inside of the semiconductor pattern 130 which has the shape of the cup. The filling insulation film 134 may include an insulation material (e.g., silicon oxide), but it is merely an example.

According to some example embodiments, the channel structure CH may further include a channel pad 136. The channel pad 136 may be formed to be connected to another end (e.g., a lower end) of the semiconductor pattern 130. The channel pad 136 may include a conductive material (e.g., polysilicon, a metal, or the like doped with an impurity), but it is merely an example.

According to some example embodiments, the bit line BL may be formed below the mold structure MS. The bit line BL may be extended in the third direction D3 to cross the gate electrode cutting pattern WLC. In addition, the bit line BL may be extended in the third direction D3 to be connected to the plurality of channel structures CH which are arranged in the third direction D3. For example, a bit line contact 182 connected to an upper portion of each of the channel structures CH may be formed in the second inter-layer insulation film 140b. The bit line BL may be electrically connected to the channel structure CH through the bit line contact 182.

According to some example embodiments, the bit line BL may be disposed below the first surface MS_S1 of the mold structure. In the first direction D1, the bit line BL may be disposed below the fourth mold stack MS4. However, it is merely an example. According to some example embodiments, the bit line BL may be disposed on the second surface MS_S2 of the mold structure. In the first direction D1, the bit line BL may be disposed on the first mold stack MS1.

According to some example embodiment, the capacitor structure CAP may be disposed to the first block BLK1. A plurality of capacitor structures CAP may be disposed.

According to some example embodiment, the capacitor structure CAP may penetrate a portion of the mold structure MS in the first block BLK1. The capacitor structure CAP may penetrate the portion of the mold structure MS in the first direction D1 from the first surface MS_S1 of the mold structure. The capacitor structure CAP may penetrate the first surface MS_S1 of the mold structure. For example, the capacitor structure CAP may penetrate the third mold stack MS3 and the fourth mold stack MS4 and may not penetrate the first mold stack MS1 and the second mold stack MS2.

According to some example embodiment, the capacitor structure CAP may penetrate the first mold portion MP1. The capacitor structure CAP may overlap the first mold portion MP1 in a direction crossing the first direction D1 (e.g., the second direction D2 or the third direction D3). For example, the direction crossing the first direction D1 may include a direction parallel to the cell substrate 100. The capacitor structure CAP may not penetrate the second mold portion MP2. The capacitor structure CAP may not overlap the second mold portion MP2 in the direction crossing the first direction D1.

According to some example embodiment, the capacitor structure CAP may be disposed in a capacitor hole CAP_H. The capacitor hole CAP_H may penetrate the mold structure MS in the first direction D1. The capacitor hole CAP_H may include a first hole portion CAP_H_P1 and a second hole portion CAP_H_P2. The first hole portion CAP_H_P1 and the second hole portion CAP_H_P2 may be disposed in the first direction D1. The first hole portion CAP_H_P1 and the second hole portion CAP_H_P2 may be connected in the first direction D1.

According to some example embodiments, the first hole portion CAP_H_P1 may penetrate the first mold portion MP1. The first hole portion CAP_H_P1 may not penetrate the second mold portion MP2. The second hole portion CAP_H_P2 may penetrate the second mold portion MP2. The second hole portion CAP_H_P2 may not penetrate the first mold portion MP1.

According to some example embodiment, the capacitor structure CAP may be disposed along the first hole portion CAP_H_P1. For example, a dielectric film 191 of the capacitor structure CAP may be extended along the first hole portion CAP_H_P1. The dielectric film 191 may not be extended along the second hole portion CAP_H_P2. An electrode film 192 may be disposed on the dielectric film 191 in the first hole portion CAP_H_P1. The electrode film 192 may not be disposed in the second hole portion CAP_H_P2.

According to some example embodiment, the capacitor structure CAP may be connected to the cap filling insulation film 193 in the first direction D1. The capacitor structure CAP may overlap the cap filling insulation film 193 in the first direction D1. The capacitor structure CAP and the cap filling insulation film 193 may not overlap in the direction crossing the first direction D1. The capacitor structure CAP may be connected to the cap filling insulation film 193 at one boundary of boundaries between the plurality of mold stacks MS1, MS2, MS3, and MS4. The capacitor structure CAP and the cap filling insulation film 193 may be in direct contact with each other to be connected at the one boundary of the boundaries between the plurality of mold stacks MS1, MS2, MS3, and MS4. For example, the capacitor structure CAP may be in contact with the cap filling insulation film 193 at the boundary between the second mold stack MS2 and the third mold stack MS3.

According to some example embodiments, the capacitor structure CAP may include the dielectric film 191 and the electrode film 192.

According to some example embodiments, the dielectric film 191 may be extended along a side surface of the electrode film 192. The dielectric film 191 may be in contact with the mold structure MS. The dielectric film 191 may surround the electrode film 192.

According to some example embodiments, the dielectric film 191 may include silicon oxide, silicon nitride, silicon oxynitride, and a high-permittivity material including a metal. The dielectric film 191 is illustrated as a single film, but it is merely for convenience for description, and it is merely an example.

According to some example embodiments, the dielectric film 191 may include a stacked layer structure in which zirconium oxide, aluminum oxide, and zirconium oxide are stacked in sequential order. The dielectric film 191 may include a dielectric film including hafnium (Hf). The dielectric film 191 may have a stacked layer structure of a ferroelectric material film and a paraelectric material film.

According to some example embodiments, the electrode film 192 may be disposed on the dielectric film 191. The electrode film 192 may be surrounded by the dielectric film 191. The electrode film 192 may include, for example, a doped semiconductor material, a conductive metallic nitride (e.g., titanium nitride, tantalum nitride, niobium nitride, tungsten nitride, or the like), a metal (e.g., ruthenium, iridium, titanium, tantalum, or the like), a conductive metallic oxide (e.g., iridium oxide, niobium oxide, or the like), and the like, but it is merely an example.

According to some example embodiments, a capacitor may be formed of the electrode film 192, the dielectric film 191, the plurality of gate electrodes GSL, WL11 to WL1n, WL21 to 2n, WL31 to WL3n, WL41 to 4n, and SSL. For example, each of the capacitor structures CAP may have an equivalent circuit in which a plurality of capacitors formed of the plurality of word lines WL, the electrode film 192, and the dielectric film 191 in between is connected in parallel.

According to some example embodiments, the capacitor structure CAP may be arranged in a shape identical to that of the channel structure CH. For example, the capacitor structure CAP may be arranged in a zigzag form. The capacitor structures CAP may be staggered in the second direction D1 and the third direction D3. The channel structures CAP may be arranged in a honeycomb form.

According to some example embodiments, a maximum width of the capacitor structure CAP and a maximum width of the channel structure CH may be equal. The maximum width of the capacitor structure CAP may be a diameter of the capacitor structure CAP at the boundaries between the mold stacks MS1, MS2, MS3, and MS4. The maximum width of the channel structure CH may be a diameter of the channel structure CH at the boundaries between the mold stacks MS1, MS2, MS3, and MS4. For example, a width of the capacitor structure CAP may be equal to a width of the cap filling insulation film 193 at the boundary between the first mold stack MS1 and the second mold stack MS2. However, it is merely an example. The maximum width of the capacitor structure CAP and the maximum width of the channel structure CH may be different.

Referring to FIG. 6, the electrode film 192 of the capacitor structure CAP may be in contact with the cap filling insulation film 193. The electrode film 192 and the cap filling insulation film 193 may be in contact with each other at a boundary between the mold stacks MS1, MS2, MS3, and MS4, at which the capacitor structure CAP and the cap filling insulation film 193 are connected. For example, an upper surface 192b of the electrode film may be in direct contact with a lower surface 193a of the cap filling insulation film at the boundary between the second mold stack MS2 and the third mold stack MS3.

According to some example embodiments, the dielectric film 191 may not cover the upper surface 192b of the electrode film. The dielectric film 191 and the electrode film 192 may not overlap each other in the first direction D1. The dielectric film 191 may be extended along the side surface of the electrode film 192. An upper surface 191b of the dielectric film and the upper surface 192b of the electrode film may be disposed on an identical plane. The upper surface 191b of the dielectric film may be in contact with the lower surface 193a of the cap filling insulation film.

Referring to FIG. 7, the electrode film 192 of the capacitor structure CAP may not be in contact with the cap filling insulation film 193. The electrode film 192 and the cap filling insulation film 193 may be spaced apart at the boundary between the plurality of mold stacks MS1, MS2, MS3, and MS4, at which the capacitor structure CAP and the cap filling insulation film 193 are connected. For example, the upper surface 192b of the electrode film may be spaced apart from the lower surface 193a of the cap filling insulation film at the boundary between the second mold stack MS2 and the third mold stack MS3 with the dielectric film 191 in between.

According to some example embodiments, in the first direction D1, the dielectric film 191 may be disposed between the electrode film 192 and the cap filling insulation film 193. The dielectric film 191 may cover the upper surface 192b of the electrode film. The dielectric film 191 and the electrode film 192 may overlap each other in the first direction D1. The dielectric film 191 may be extended along the upper surface 192b of the electrode film. The upper surface 191b of the dielectric film may be disposed at a height level different from that of the upper surface 192b of the electrode film. The upper surface 191b of the dielectric film may be disposed above the upper surface 192b of the electrode film toward the cap filling insulation film 193. The upper surface 191b of the dielectric film may be in contact with the lower surface 193a of the cap filling insulation film.

According to some example embodiment, the cap filling insulation film 193 may be disposed to the first block BLK1. A plurality of cap filling insulation films 193 may be disposed.

According to some example embodiment, the cap filling insulation film 193 may penetrate a portion of the mold structure MS in the first block BLK1. The cap filling insulation film 193 may penetrate the portion of the mold structure MS from the second surface MS_S2 of the mold structure. The cap filling insulation film 193 may penetrate the second surface MS_S2 of the mold structure. The cap filling insulation film 193 may be connected to the second surface MS_S2 of the mold structure. For example, the cap filling insulation film 193 may penetrate the first mold stack MS1 and the second mold stack MS2 and may not penetrate the third mold stack MS3 and the fourth mold stack MS4.

According to some example embodiment, the cap filling insulation film 193 may be connected to the capacitor structure CAP in the first direction D1. The cap filling insulation film 193 may overlap the capacitor structure CAP in the first direction D1. The cap filling insulation film 193 may be connected to the capacitor structure CAP at one boundary of the boundaries between the plurality of mold stacks MS1, MS2, MS3, and MS4. For example, the cap filling insulation film 193 may be in contact with the capacitor structure CAP at the boundary between the second mold stack MS2 and the third mold stack MS3.

According to some example embodiments, the cap filling insulation film 193 may include, for example, at least one of silicon oxide, silicon oxynitride, and the low-permittivity (low-k) material having the permittivity lower than that of silicon oxide, but it is merely an example.

According to some example embodiment, the cap filling insulation film 193 may penetrate the second mold portion MP2. The cap filling insulation film 193 may overlap the second mold portion MP2 in the direction crossing the first direction D1. The cap filling insulation film 193 may not penetrate the first mold portion MP1. The cap filling insulation film 193 may not overlap the first mold portion MP1 in the direction crossing the first direction D1.

According to some example embodiment, the cap filling insulation film 193 may be disposed in the capacitor hole CAP_H. The cap filling insulation film 193 may be disposed along the second hole portion CAP_H_P2. The cap filling insulation film 193 may fill the second hole portion CAP_H_P2. The cap filling insulation film 193 may not be extended along the first hole portion CAP_H_P1.

According to some example embodiment, the capacitor structure CAP and the cap filling insulation film 193 may have a step at a boundary surface at which each is in contact with another. For example, the capacitor structure CAP and the cap filling insulation film 193 may have the step at the boundary between the second mold stack MS2 and the third mold stack MS3, at which the capacitor structure CAP and the cap filling insulation film 193 are in contact with and connected to each other, among the boundaries between the plurality of mold stacks MS1, MS2, MS3, and MS4.

According to some example embodiments, in the direction crossing the first direction D1 (e.g., the second direction D2 or the third direction D3), a width of a first bonding surface of the capacitor structure CAP in contact with the cap filling insulation film 193 and a width of a second bonding surface of the cap filling insulation film 193 in contact with the capacitor structure CAP may be different from each other.

As an example, referring to FIG. 6, the first bonding surface of the capacitor structure CAP in contact with the cap filling insulation film 193 may include the upper surface 191b of the dielectric film and the upper surface 192b of the electrode film. The second bonding surface of the cap filling insulation film 193 in contact with the capacitor structure CAP may be the lower surface 193a of the cap filling insulation film. In the second direction D2 or the third direction D3 crossing the first direction D1, the width of the first bonding surface of the capacitor structure CAP, which includes the upper surface 191b of the dielectric film and the upper surface 192b of the electrode film, may be different from the width of the second bonding surface of the cap filling insulation film 193, which includes the lower surface 193a of the cap filling insulation film. In the second direction D2, the width of the first bonding surface of the capacitor structure CAP may be smaller than the width of the second bonding surface of the cap filling insulation film 193. However, it is merely an example. The width of the first bonding surface of the capacitor structure CAP may be also larger than the width of the second bonding surface of the cap filling insulation film 193.

As another example, referring to FIG. 7, the first bonding surface of the capacitor structure CAP in contact with the cap filling insulation film 193 may be the upper surface 191b of the dielectric film. The second bonding surface of the cap filling insulation film 193 in contact with the capacitor structure CAP may be the lower surface 193a of the cap filling insulation film. In the second direction D2 or the third direction D3 crossing the first direction D1, the width of the first bonding surface of the capacitor structure CAP, which includes the upper surface 191b of the dielectric film, may be different from the width of the second bonding surface of the cap filling insulation film 193, which includes the lower surface 193a of the cap filling insulation film. In the second direction D2, the width of the first bonding surface of the capacitor structure CAP may be smaller than the width of the second bonding surface of the cap filling insulation film 193.

According to some example embodiments, in the first direction D1, a height of the capacitor structure CAP and a height of the cap filling insulation film 193 may be equal. The height of the cap filling insulation film 193 which penetrates the first mold stack MS1 and the second mold stack MS2 and the height of the capacitor structure CAP which penetrates the third mold stack MS3 and the fourth mold stack MS4 may be equal. However, it is merely an example. For example, when a height of the first mold stack MS1 and the second mold stack MS2 and a height of the third mold stack MS3 and the fourth mold stack MS4 in the first direction D1 are different, the height of the capacitor structure CAP and the height of the cap filling insulation film 193 in the first direction D1 may be different from each other.

According to some example embodiments, in the first direction D1, the capacitor structure CAP may be disposed to be further adjacent to the bit line BL than the cap filling insulation film 193. Since the bit line BL is disposed below the fourth mold stack MS4, the capacitor structure CAP which penetrates the third mold stack MS3 and the fourth mold stack MS4 may be disposed to be further adjacent to the bit line BL compared to the cap filling insulation film 193 which penetrates the first mold stack MS1 and the second mold stack MS2.

According to some example embodiment, the capacitor structure CAP may be connected to a cap connection wiring 170 through a cap connection contact 184. The cap connection wiring 170 may be electrically connected to the electrode film 192 of the capacitor structure CAP.

According to some example embodiments, in the first direction D1, the cap connection wiring 170 may be disposed at a height level equal to that of the bit line BL. The cap connection wiring 170 may be formed below the mold structure MS. The cap connection wiring 170 may be disposed abovebelow the first surface MS_S1 of the mold structure. In the first direction D1, the cap connection wiring 170 may be disposed abovebelow the fourth mold stack MS4. The cap connection wiring 170 may be spaced apart from the bit line BL. For example, the cap connection wiring 170 may be spaced apart from the bit line BL in the third direction D3.

According to some example embodiments, the capacitor structure CAP may reduce noise in an input/output signal applied to the semiconductor memory device through the input/output pad 320. As a height of the mold structure MS is increased in the first direction D1, resistance occurring in the mold structure MS may be increased. Thus, as the capacitor structure CAP does not penetrate the entire mold structure MS and penetrates only a portion of the mold structure MS in the first direction D1, an influence of the resistance on the capacitor structure CAP due to an increased level of the mold structure MS may be decreased, and a more efficient capacitor capacity of the capacitor structure CAP may be implemented.

According to some example embodiments, an electrode connection structure TAP may penetrate the mold structure MS in the first block BLK1 in the first direction D1. Accordingly, the electrode connection structure TAP may be connected to the plurality of gate electrodes GSL, WL11 to WL1n, WL21 to 2n, WL31 to WL3n, WL41 to 4n, and SSL by penetrating the mold structure MS. Accordingly, the electrode connection structure TAP may connect the plurality of gate electrodes GSL, WL11 to WL1n, WL21 to 2n, WL31 to WL3n, WL41 to 4n, and SSL.

According to some example embodiments, the electrode connection structure TAP may be spaced apart from the capacitor structure CAP in the second direction D2. For example, the electrode connection structure TAP may be disposed between the plurality of capacitor structures CAP in the second direction D2. The electrode connection structure TAP may include a conductive material (e.g., a metal such as tungsten (W), cobalt (Co), or nickel (Ni) or a semiconductor material such as silicon), but it is merely an example.

According to some example embodiments, the cell wiring structure 180 may be formed on the mold structure MS. The cell wiring structure 180 may be disposed on the first surface MS_S1 of the mold structure. For example, a first inter-wiring insulation film 145 may be formed on the second inter-layer insulation film 140b, and the cell wiring structure 180 may be formed in the first inter-wiring insulation film 145. The cell wiring structure 180 may be electrically connected to the bit line BL, the cell contact 162, a source contact 164, and the contact plug 166. Through this, the cell wiring structure 180 may be electrically connected to the channel structure CH, the plurality of gate electrodes GSL, WL11 to WL1n, WL21 to 2n, WL31 to WL3n, WL41 to 4n, and SSL, and the cell substrate 100. The number of layers, disposition, and the like of the cell wiring structure 180, which are illustrated, are merely examples.

According to some example embodiments, the cell wiring structure 180 may be electrically connected to the plurality of memory cells formed in the cell array region CAR. For example, the cell wiring structure 180 may be electrically connected to the bit line BL. Through this, the cell wiring structure 180 may be electrically connected to the channel structure CH. Also, as being electrically connected to the cell contact 162, the cell wiring structure 180 may be electrically connected to the plurality of gate electrodes GSL, WL11 to WL1n, WL21 to 2n, WL31 to WL3n, WL41 to 4n, and SSL.

According to some example embodiments, the cell contact 162 may be connected to the plurality of gate electrodes GSL, WL11 to WL1n, WL21 to 2n, WL31 to WL3n, WL41 to 4n, and SSL. For example, the cell contact 162 may be extended in the first inter-layer insulation film 140a and the second inter-layer insulation film 140b in the first direction D1 to be connected to the plurality of gate electrodes GSL, WL11 to WL1n, WL21 to 2n, WL31 to WL3n, WL41 to 4n, and SSL. In some example embodiments, the cell contact 162 may have a bent portion at the boundary between the second mold stack MS2 and the third mold stack MS3. However, it is merely an example. For example, similarly to the channel structure CH, the cell contact 162 may have bent portions between the first mold stack MS1 and the second mold stack MS2, between the second mold stack MS2 and the third mold stack MS3, and between the third mold stack MS3 and the fourth mold stack MS4.

According to some example embodiments, the source contact 164 may be connected to the cell substrate 100. For example, the source contact 164 may be extended in the first inter-layer insulation film 140a and the second inter-layer insulation film 140b in the first direction D1 to be connected to the cell substrate 100. The source contact 164 may electrically connect the cell substrate 100 and the cell wiring structure 180.

According to some example embodiment, each of the cell contact 162 and the source contact 164 may be connected to the cell wiring structure 180 by a contact via 186.

According to some example embodiments, the peripheral circuit structure PERI may include a peripheral circuit substrate 200, a peripheral circuit element PT, and a peripheral circuit wiring structure 260.

According to some example embodiments, the peripheral circuit substrate 200 may be disposed below the cell substrate 100. For example, the peripheral circuit substrate 200 may be opposite to the first surface 100a of the cell substrate. According to some example embodiments, the peripheral circuit substrate 200 may include, for example, a semiconductor substrate such as a silicon substrate, a germanium substrate, or a silicon-germanium substrate. Alternatively, the peripheral circuit substrate 200 may include a silicon-on-insulator (SOI) substrate, a germanium-on-insulator (GOI) substrate, or the like.

According to some example embodiments, the peripheral circuit element PT may be formed on the peripheral circuit substrate 200. The peripheral circuit element PT may form a peripheral circuit (e.g., the peripheral circuit 30 of FIG. 1) that controls an operation of the semiconductor memory device. For example, the peripheral circuit element PT may include a control logic (e.g., the control logic 37 of FIG. 1), a row decoder (e.g., the row decoder 33 of FIG. 1), a page buffer (e.g., the page buffer 35 of FIG. 1), and the like. In the following description, a surface of the peripheral circuit substrate 200 on which the peripheral circuit element is disposed may be referred to as a first surface 200a of the peripheral circuit substrate. The first surface 200a of the peripheral circuit substrate may be a front side of the peripheral circuit substrate 200. In contrast, a surface of the peripheral circuit substrate 200 opposite to the first surface 200a of the peripheral circuit substrate may be referred to as a second surface 200b of the peripheral circuit substrate. The second surface 200b of the peripheral circuit substrate may be a back side of the peripheral circuit substrate.

According to some example embodiments, the peripheral circuit element PT may include, for example, a transistor, but it is merely an example. For example, the peripheral circuit element PT may include not only various active elements such as the transistor but also various passive elements such as a capacitor, a resistor, or an inductor.

According to some example embodiments, the cell structure CELL may be stacked on the peripheral circuit structure PERI. For example, the cell structure CELL may be stacked on the first surface 200a of the peripheral circuit substrate.

According to some example embodiments, the first substrate 100a of the cell substrate may be opposite to the peripheral circuit structure PERI. For example, the first substrate 100a of the cell substrate may be opposite to the first surface 200a of the peripheral circuit substrate.

According to some example embodiments, the semiconductor memory device may have a chip-to-chip (C2C) structure. The C2C structure may be a structure in which an upper chip including the cell structure CELL on a first wafer (e.g., the cell substrate 100) is produced, and a lower chip including the peripheral circuit structure PERI on a second wafer (e.g., the peripheral circuit substrate 200) different from the first wafter is produced, and then the upper chip and the lower chip are connected to each other with a bonding scheme.

As an example, the bonding scheme may be a scheme of electrically connecting, to each other, a first bonding metal 195 formed in an uppermost metallic layer of the upper chip and a second bonding metal 295 formed in an uppermost metallic layer of the lower chip. For example, when the first bonding metal 195 and the second bonding metal 295 are formed of copper (Cu), the bonding scheme may be a Cu—Cu bonding scheme. However, it is merely an example. The first bonding metal 195 and the second bonding metal 295 may be also formed of other various metals such as aluminum (Al) or tungsten (W).

According to some example embodiments, as the first bonding metal 195 and the second bonding metal 295 are bonded, the cell wiring structure 180 may be connected to the peripheral circuit wiring structure 260. Through this, the bit line BL each gate electrode GSL, WL, or SSL and/or the cell substrate 100 may be connected to the peripheral circuit element PT.

According to some example embodiments, the input/output pad 320 may be disposed above the second surface 100b of the cell substrate 100. For example, a third inter-layer insulation film 310 covering the cell substrate 100 and the insulation substrate 101 may be formed on the second surface 100b of the cell substrate 100. The input/output pad 320 may be formed on the third inter-layer insulation film 310. The third inter-layer insulation film 310 may include, for example, at least one of silicon oxide, silicon oxynitride, and the low-permittivity (low-k) material having the permittivity lower than that of silicon oxide, but it is merely an example.

According to some example embodiments, the input/output pad 320 may be electrically connected to the cell structure CELL and/or the peripheral circuit structure PERI. For example, the contact plug 166 which connects the cell wiring structure 180 and the input/output pad 320 may be formed. The contact plug 166 may penetrate inter-layer insulation films 140a, 140b, and 310. The inter-layer insulation films 140a, 140b, and 310 may cover the mold structure MS. The contact plug 166 may be, for example, extended in the first direction D1 to penetrate the third inter-layer insulation film 310, the insulation substrate 101, the first inter-layer insulation film 140a, and the second inter-layer insulation film 140b. The input/output pad 320 may be electrically connected to the cell wiring structure 180 through the contact plug 166.

According to some example embodiments, the contact plug 166 may be electrically connected to the capacitor structure CAP through the cell wiring structure 180 and the cap connection wiring 170. The capacitor structure CAP may receive, through the cell wiring structure 180 and the cap connection wiring 170, a signal that is input and output through the input/output pad 320 and the contact plug 166 and may reduce noise in the signal by using capacitance of the capacitor structure CAP.

According to some example embodiments, a width of the contact plug 166 may be decreased as approaching the cell wiring structure 180. This may be due to a property of an etching process for forming the contact plug 166.

According to some example embodiments, a capping insulation film 330 may be disposed on the input/output pad 320. The capping insulation film 330 may include a pad opening OP that exposes at least a portion of the input/output pad 320. The input/output pad 320 may be electrically connected to an external device or the like through the pad opening OP.

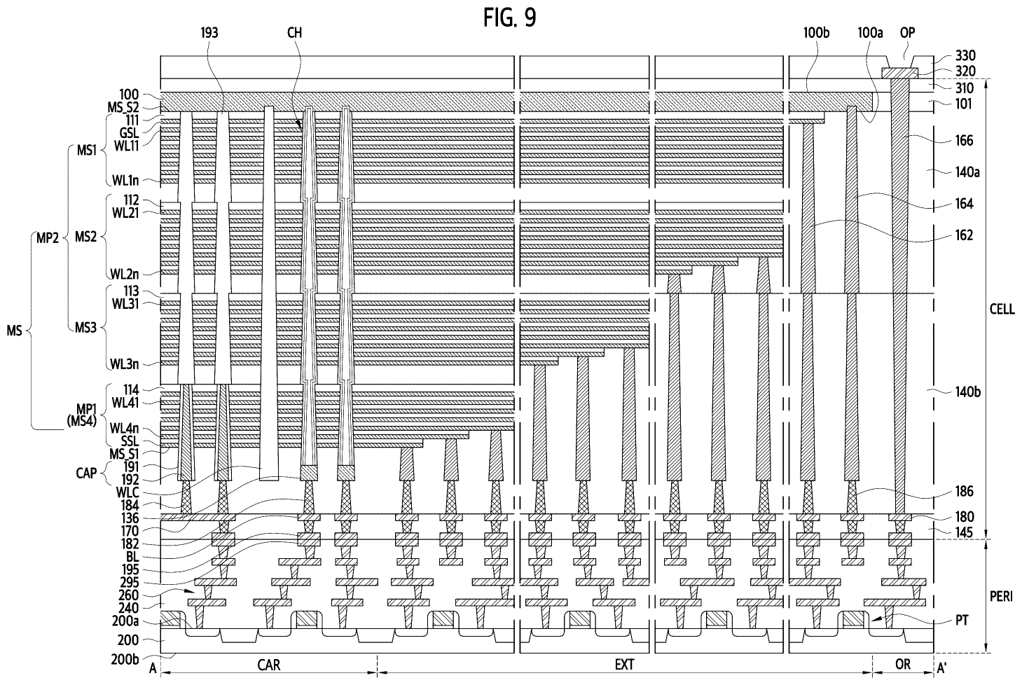

FIG. 9 is another example diagram illustrating a cross section taken along line A-A′ of FIG. 3 for describing a semiconductor memory device according to some other example embodiments. In order to describe the semiconductor memory device according to some other example embodiments, a description will mainly focus on different aspect(s) from that described above with reference to FIGS. 3 through 8.

Referring to FIG. 9, the capacitor structure CAP may penetrate the fourth mold stack MS4 and may not penetrate the first mold stack MS1, the second mold stack MS2, and the third mold stack MS3. In the second direction D2 and the third direction D3, the capacitor structure CAP may overlap the fourth mold stack MS4 and may not overlap the first mold stack MS1, the second mold stack MS2, and the third mold stack MS3.

According to some example embodiments, the cap filling insulation film 193 may penetrate the first mold stack MS1, the second mold stack MS2, and the third mold stack MS3 and may not penetrate the fourth mold stack MS4. In the second direction D2 and the third direction D3, the cap filling insulation film 193 may overlap the first mold stack MS1, the second mold stack MS2, and the third mold stack MS3 and may not overlap the fourth mold stack MS4.

According to some example embodiments, the first mold portion MP1 may include the fourth mold stack MS4, and the second mold portion MP2 may include the first mold stack MS1, the second mold stack MS2, and the third mold stack MS3.

According to some example embodiments, the capacitor structure CAP and the cap filling insulation film 193 may be connected at a boundary between the third mold stack MS3 and the fourth mold stack MS4. The capacitor structure CAP and the cap filling insulation film 193 may be connected to each other with a step at the boundary between the third mold stack MS3 and the fourth mold stack MS4.

According to some example embodiments, in the first direction D1, a height of the capacitor structure CAP and a height of the cap filling insulation film 193 may be different. In the first direction D1, the height of the capacitor structure CAP which penetrates the fourth mold stack MS4 may be smaller than the height of the cap filling insulation film 193 which penetrates the first mold stack MS1, the second mold stack MS2, and the third mold stack MS3.

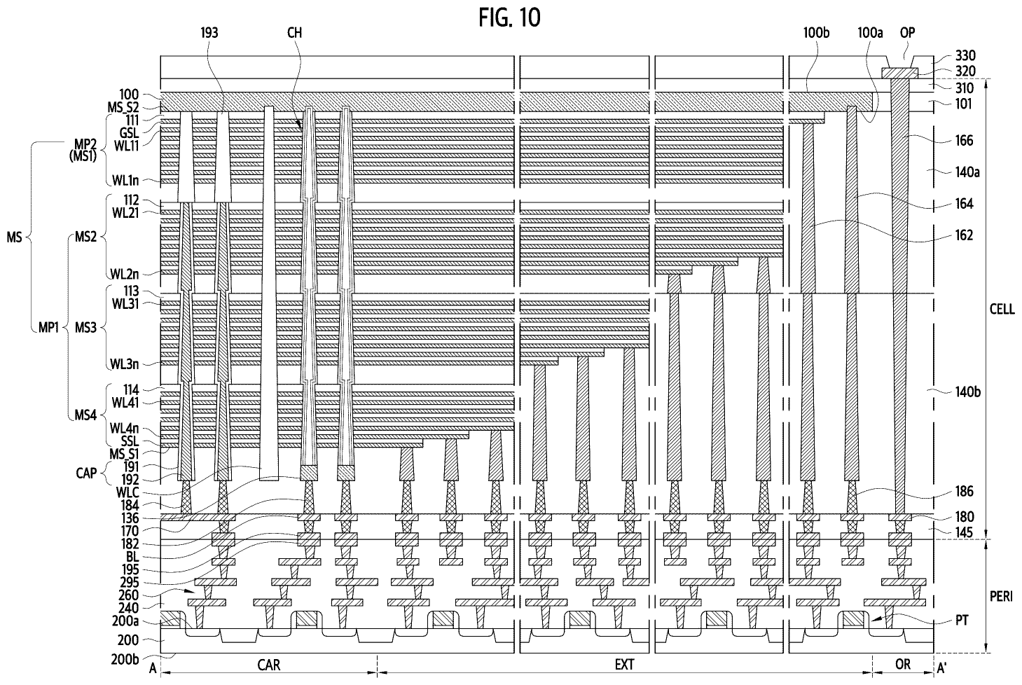

FIG. 10 is another example diagram illustrating a cross section taken along line A-A′ of FIG. 3 for describing a semiconductor memory device according to still some other example embodiments. In order to describe the semiconductor memory device according to still some other example embodiments, a description will mainly focus on different aspect(s) from that described above with reference to FIGS. 3 through 8.

Referring to FIG. 10, the capacitor structure CAP may penetrate the second mold stack MS2, the third mold stack MS3, and the fourth mold stack MS4 and may not penetrate the first mold stack MS1. In the second direction D2 and the third direction D3, the capacitor structure CAP may overlap the second mold stack MS2, the third mold stack MS3, and the fourth mold stack MS4 and may not overlap the first mold stack MS1.

According to some example embodiments, the cap filling insulation film 193 may penetrate the first mold stack MS1 and may not penetrate the second mold stack MS2, the third mold stack MS3, and the fourth mold stack MS4. In the second direction D2 and the third direction D3, the cap filling insulation film 193 may overlap the first mold stack MS1 and may not overlap the second mold stack MS2, the third mold stack MS3, and the fourth mold stack MS4.

According to some example embodiments, the first mold portion MP1 may include the second mold stack MS2, the third mold stack MS3, and the fourth mold stack MS4, and the second mold portion MP2 may include the first mold stack MS1.

According to some example embodiments, the capacitor structure CAP and the cap filling insulation film 193 may be connected at a boundary between the first mold stack MS1 and the second mold stack MS2. The capacitor structure CAP and the cap filling insulation film 193 may be connected to each other with a step at the boundary between the first mold stack MS1 and the second mold stack MS2.

According to some example embodiments, in the first direction D1, a height of the capacitor structure CAP and a height of the cap filling insulation film 193 may be different. In the first direction D1, the height of the capacitor structure CAP which penetrates the second mold stack MS2, the third mold stack MS3, and the fourth mold stack MS3 may be larger than the height of the cap filling insulation film 193 which penetrates the first mold stack MS1.

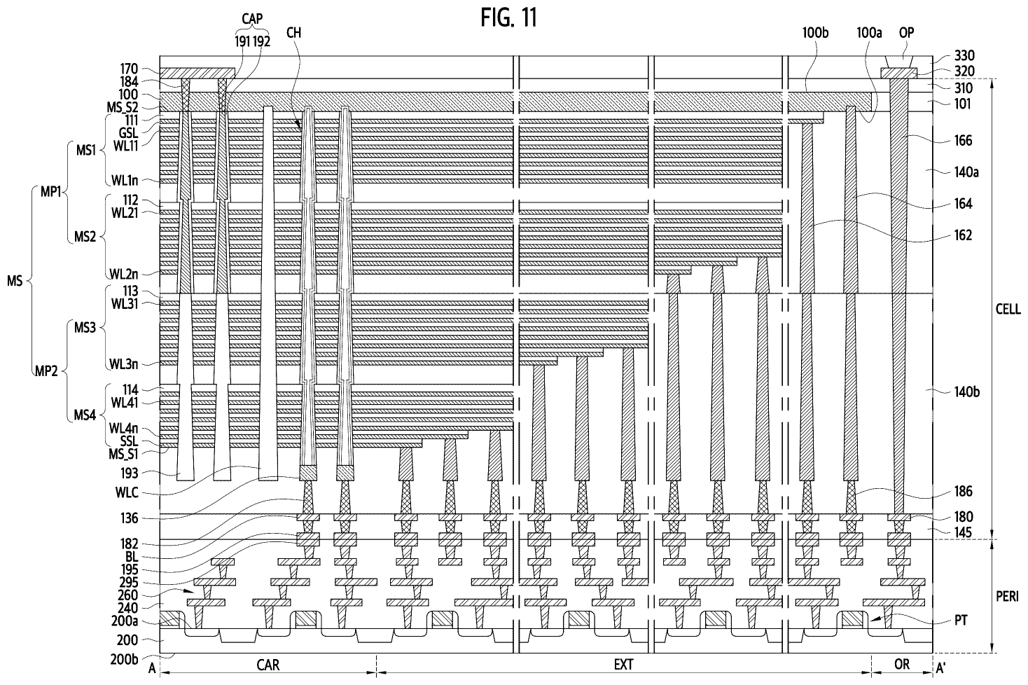

FIG. 11 is another example diagram illustrating a cross section taken along line A-A′ of FIG. 3 for describing a semiconductor memory device according to still some other example embodiments. In order to describe the semiconductor memory device according to still some other example embodiments, a description will mainly focus on different aspect(s) from that described above with reference to FIGS. 3 through 8.

Referring to FIG. 11, the capacitor structure CAP may penetrate a portion of the mold structure MS from the second surface MS_S2 of the mold structure. The capacitor structure CAP may be connected to the second surface MS_S2 of the mold structure. The capacitor structure CAP may penetrate the second surface MS_S2 of the mold structure. The capacitor structure CAP may penetrate the first mold stack MS1 and the second mold stack MS2.

According to some example embodiments, the cap filling insulation film 193 may penetrate a portion of the mold structure MS from the first surface MS_S1 of the mold structure. The cap filling insulation film 193 may penetrate the first surface MS_S1 of the mold structure. The cap filling insulation film 193 may penetrate the third mold stack MS3 and the fourth mold stack MS4.

According to some example embodiments, the first mold portion MP1 may include the first mold stack MS1 and the second mold stack MS2, and the second mold portion MP2 may include the third mold stack MS3 and the fourth mold stack MS4.

According to some example embodiments, the cap connection wiring 170 which is connected to the capacitor structure CAP may be disposed on the second surface MS_S2 of the mold structure. In the first direction D1, the cap connection wiring 170 and the bit line BL may be disposed opposite to each other with the mold structure MS in between. The cap connection wiring 170 may be disposed in the capping insulation film 330. As an example, the cap connection wiring 170 may be electrically connected to the input/output pad 320 through a wiring structure. As another example, when the pad opening OP is formed on the cap connection wiring 170, the cap connection wiring 170 may be used as an input/output pad.

According to some example embodiments, in the first direction D1, the cap filling insulation film 193 may be disposed to be further adjacent to the bit line BL than the capacitor structure CAP. Since the bit line BL is disposed on the fourth mold stack MS4, the cap filling insulation film 193 which penetrates the third mold stack MS3 and the fourth mold stack MS4 may be disposed to be further adjacent to the bit line BL compared to the capacitor structure CAP which penetrates the first mold stack MS1 and the second mold stack MS2.

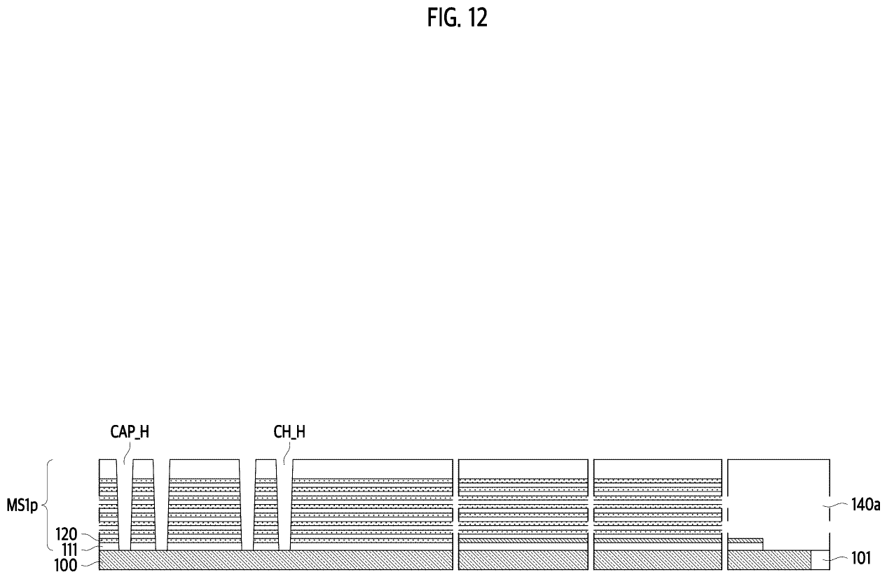

FIGS. 12 through 28 are diagrams illustrating operations for describing a method for manufacturing a semiconductor memory device according to some example embodiments.

Referring to FIG. 12, a pre-first mold stack MS1p and the first inter-layer insulation film 140a may be formed on the cell substrate 100 and the insulation substrate 101. The pre-first mold stack MS1p may include a mold sacrificial film 120 and a first mold insulation film 111 that are alternately stacked. The mold sacrificial film 120 may include a material having an etch selectivity for the first mold insulation film 111. For example, the first mold insulation film 111 may include a silicon oxide film, and the mold sacrificial film 120 may include a silicon nitride film.

Then, the capacitor hole CAP_H and a channel hole CH_H which penetrate the pre-first mold stack MS1p and the first inter-layer insulation film 140a may be formed.

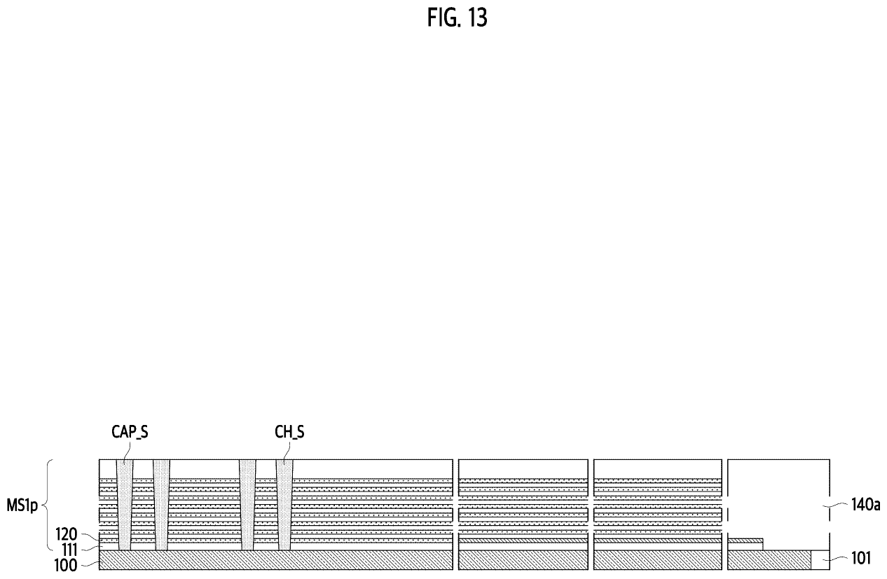

Referring to FIG. 13, a capacitor sacrificial film CAP_S filling the capacitor hole CAP_H (of FIG. 12) and a channel sacrificial film CH_S filling the channel hole CH_H (of FIG. 12) may be formed. The capacitor sacrificial film CAP_S and the channel sacrificial film CH_S may include, for example, carbon.

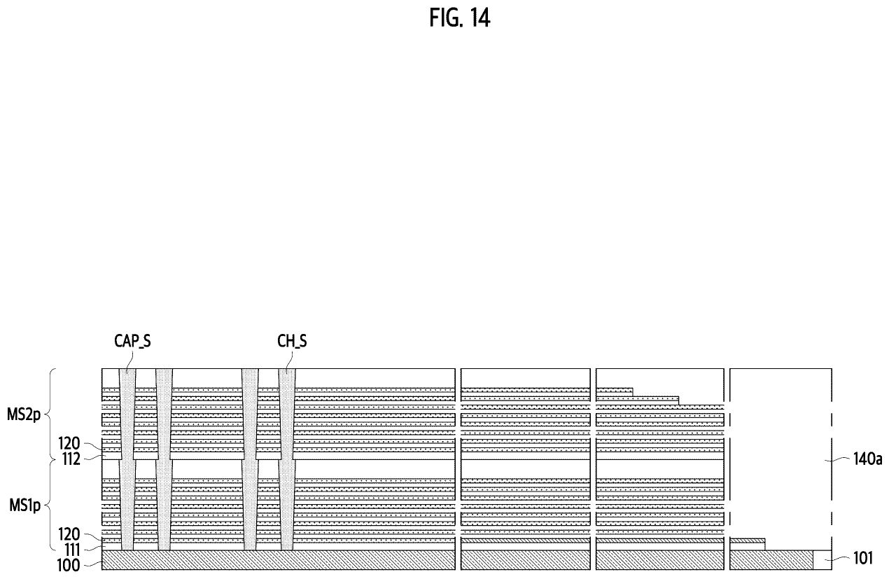

Referring to FIG. 14, a pre-second mold stack MS2p may be formed on the pre-first mold stack MS1p. The pre-second mold stack MS2p may include the mold sacrificial film 120 and a second mold insulation film 112 that are alternately stacked. The inter-layer insulation film 140a may be formed on the pre-second mold stack MS2p.

Then, the capacitor hole and the channel hole which penetrate the pre-second mold stack MS2p in a way similar to that in FIG. 12 may be formed. The capacitor hole and the channel hole which penetrate the pre-second mold stack MS2p may be formed on the capacitor sacrificial film CAP_S and the channel sacrificial film CH_S which penetrate the pre-first mold stack MS1p, respectively. The capacitor hole and the channel hole which penetrate the pre-second mold stack MS2p may be formed so as to expose surfaces of the capacitor sacrificial film CAP_S and the channel sacrificial film CH_S which penetrate the pre-first mold stack MS1p, respectively.

Then, the capacitor sacrificial film CAP_S and the channel sacrificial film CH_S may be formed in the capacitor hole and the channel hole which penetrate the pre-second mold stack MS2p, respectively. The capacitor sacrificial film CAP_S and the channel sacrificial film CH_S which penetrate the pre-second mold stack MS2p may be connected to the capacitor sacrificial film CAP_S and the channel sacrificial film CH_S which penetrate the pre-first mold stack MS1p, respectively. Thus, each of the capacitor sacrificial film CAP_S and the channel sacrificial film CH_S may be formed to penetrate the pre-first mold stack MS1p and the pre-second mold stack MS2p.

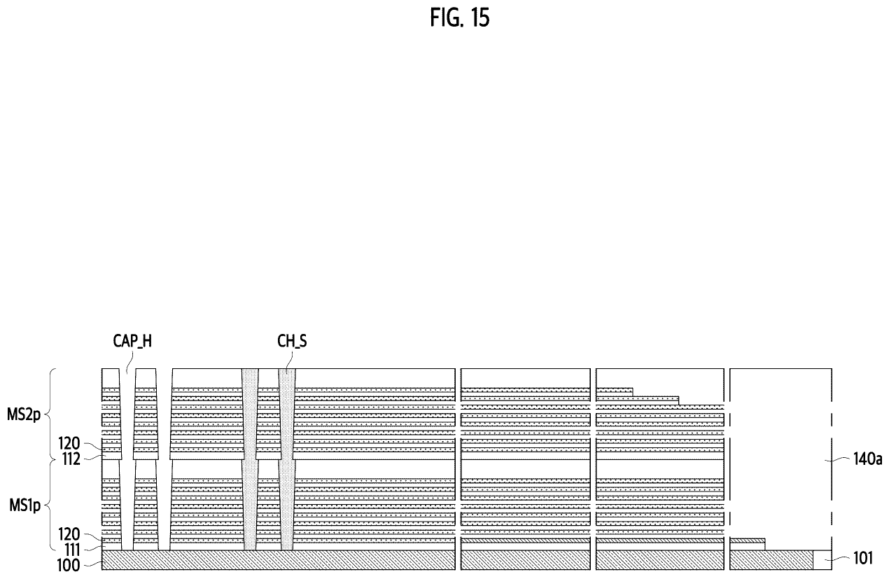

Referring to FIG. 15, the capacitor sacrificial film CAP_S (of FIG. 14) which penetrates the pre-first mold stack MS1p and the pre-second mold stack MS2p may be removed. The channel sacrificial film CH_S which penetrates the pre-first mold stack MS1p and the pre-second mold stack MS2p may be maintained without being removed. The mold sacrificial film 120, the first mold insulation film 111, and the second mold insulation film 112 may be exposed through the capacitor hole CAP_H which penetrates the pre-second mold stack MS2p.

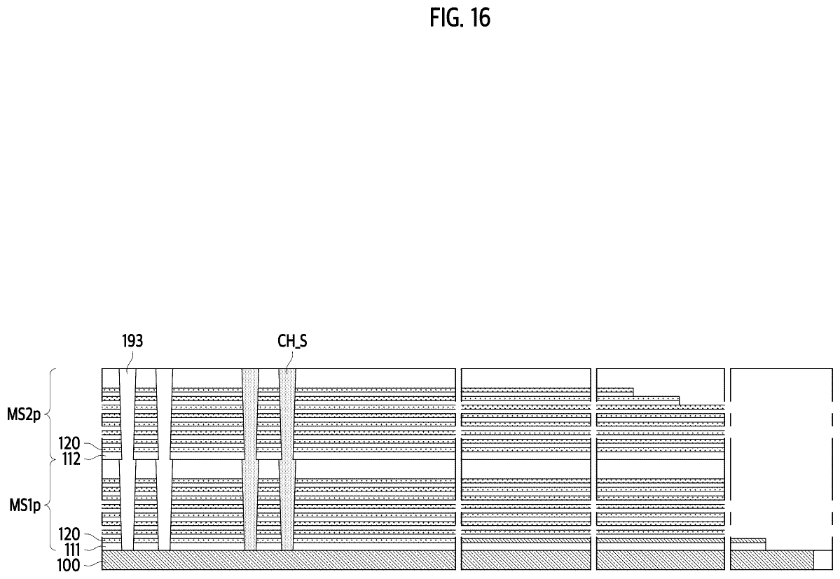

Referring to FIG. 16, the cap filling insulation film 193 may be formed in the capacitor hole CAP_H (of FIG. 15). The cap filling insulation film 193 may fill the capacitor hole CAP_H (of FIG. 15).

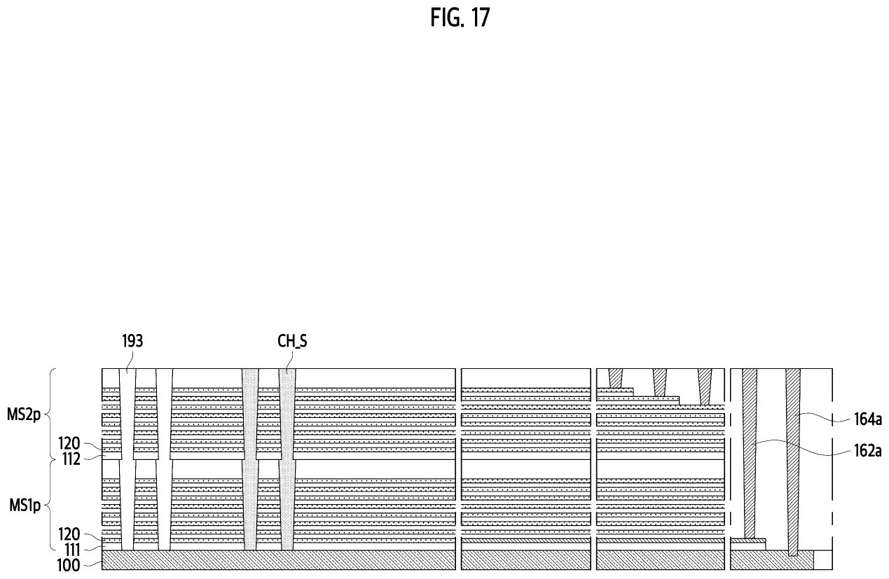

Referring to FIG. 17, a first portion 162a of a cell contact and a first portion 164a of a source contact that penetrate the first inter-layer insulation film 140a may be formed.

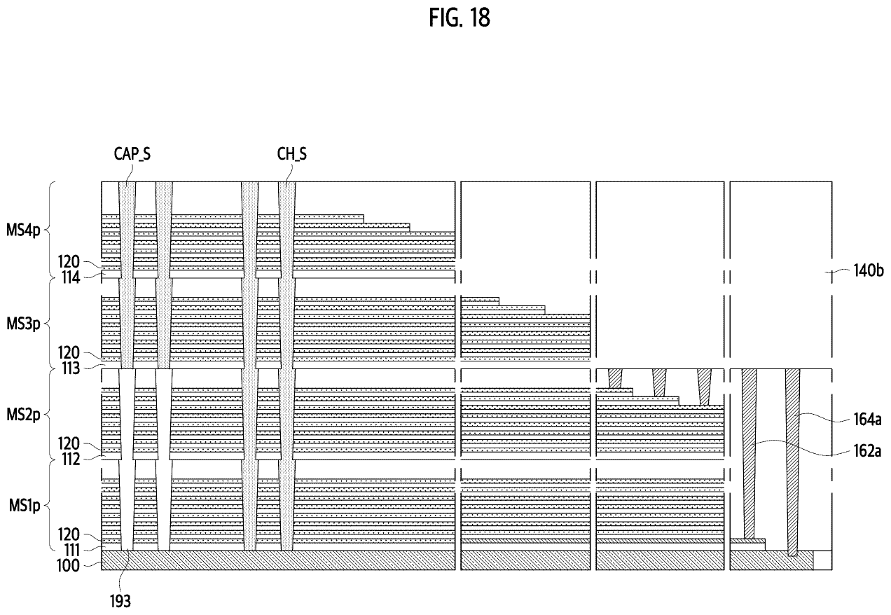

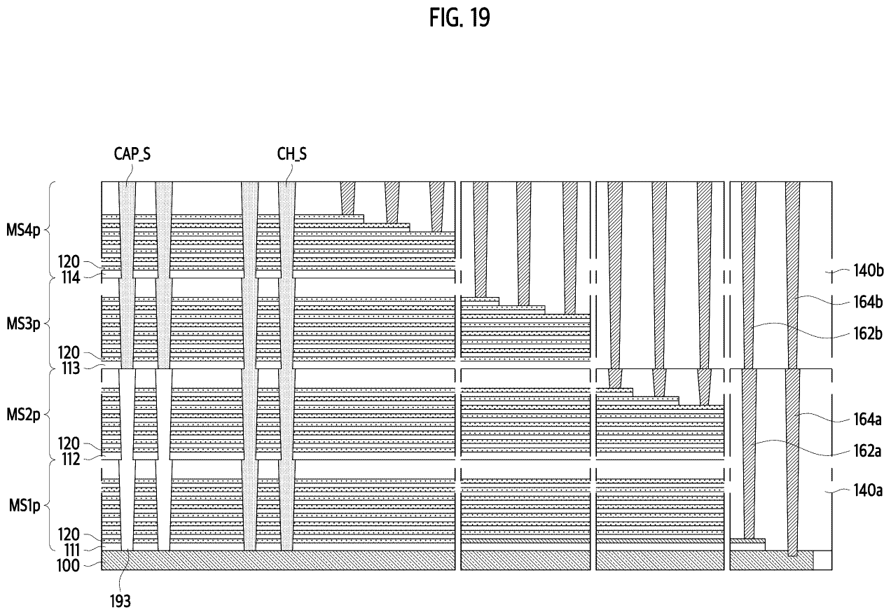

Referring to FIG. 18 and FIG. 19, the capacitor sacrificial film CAP_S and the channel sacrificial film CH_S which penetrate a pre-third mold stack MS3p and a pre-fourth mold stack MS4p may be formed by identically repeating operations of FIGS. 12 through 17. The capacitor sacrificial film CAP_S which penetrates the pre-third mold stack MS3p and the pre-fourth mold stack MS4p may be formed so as to be connected to the cap filling insulation film 193 which penetrates the pre-first mold stack MS1p and the pre-second mold stack MS2p.

Then, a second portion 162b of the cell contact and a second portion 164b of the source contact that penetrate the second inter-layer insulation film 140b may be formed. The second portion 162b of the cell contact may be formed so as to be connected to the first portion 162a of the cell contact. The first portion 164a of the source contact may be formed so as to be connected to the second portion 164b of the source contact.

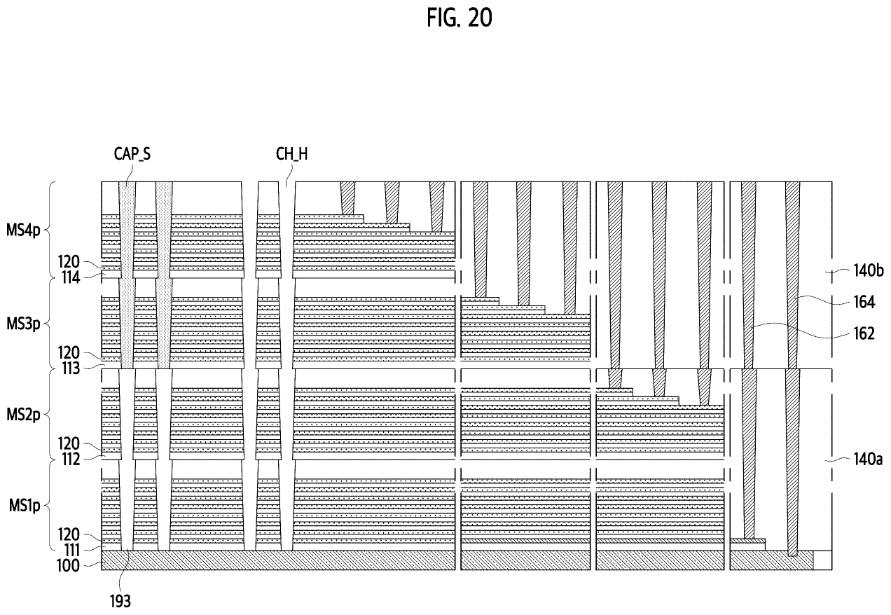

Referring to FIG. 20, the channel sacrificial film CH_S (of FIG. 19) may be removed, so that the channel hole CH_H may be formed. When the channel sacrificial film CH_S (of FIG. 19) is removed, the capacitor sacrificial film CAP_S may not be removed.

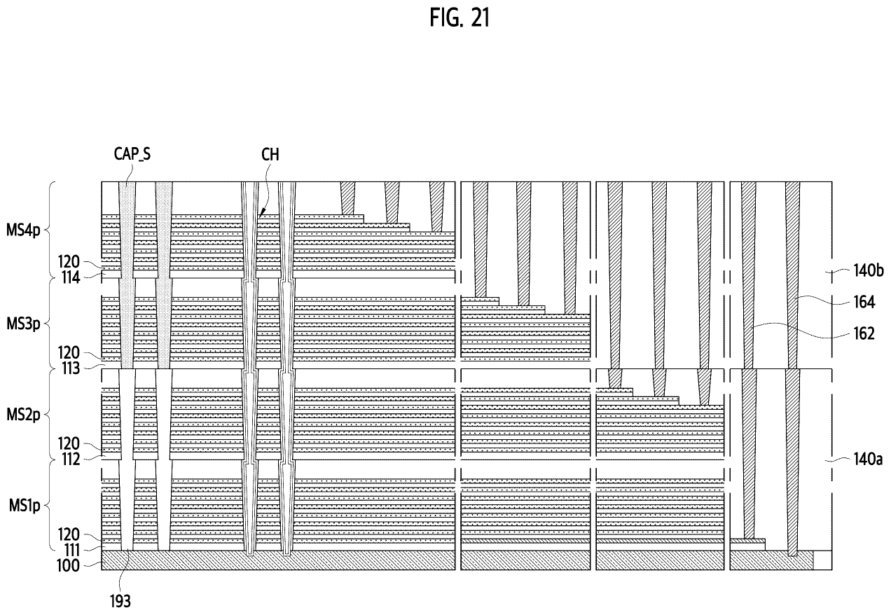

Referring to FIG. 21, the channel structure CH may be formed in the channel hole CH_H (of FIG. 20). The information storage film 132 (of FIG. 5), the semiconductor pattern 130 (of FIG. 5), and the filling insulation film 134 (of FIG. 5) may be formed in the channel hole CH_H (of FIG. 20) in sequential order.

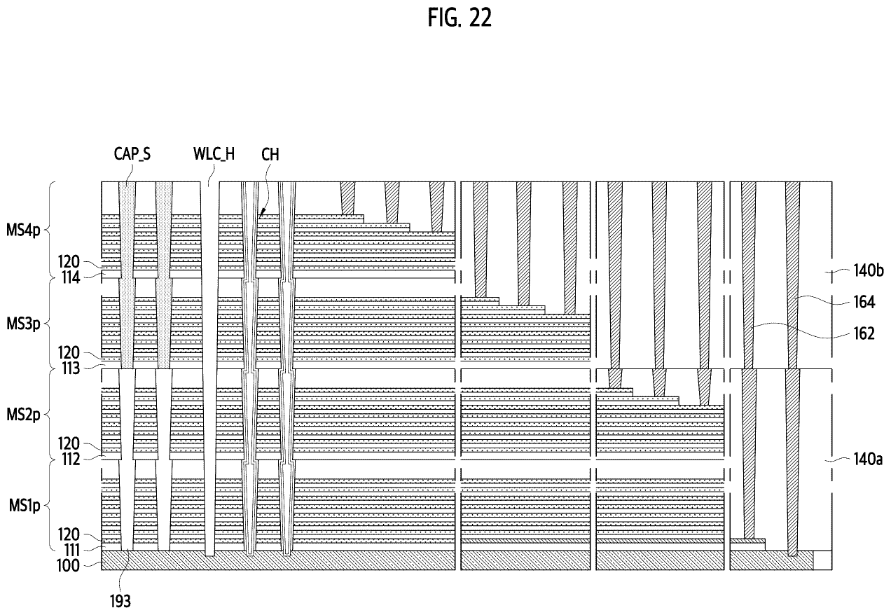

Referring to FIG. 22, a gate cutting pattern hole WLC_H penetrating the pre-first mold stack MS1p, the pre-second mold stack MS2p, the pre-third mold stack MS3p, and the pre-fourth mold stack MS4p may be formed. The gate cutting pattern hole WLC_H may be formed between the capacitor sacrificial film CAP_H and the channel structure CH. Referring to FIG. 22, the mold sacrificial film 120 and the mold insulation films 111, 112, 113, and 114 of the pre-first mold stack MS1p, the pre-second mold stack MS2p, the pre-third mold stack MS3p, and the pre-fourth mold stack MS4p may be exposed in the gate cutting pattern hole WLC_H.

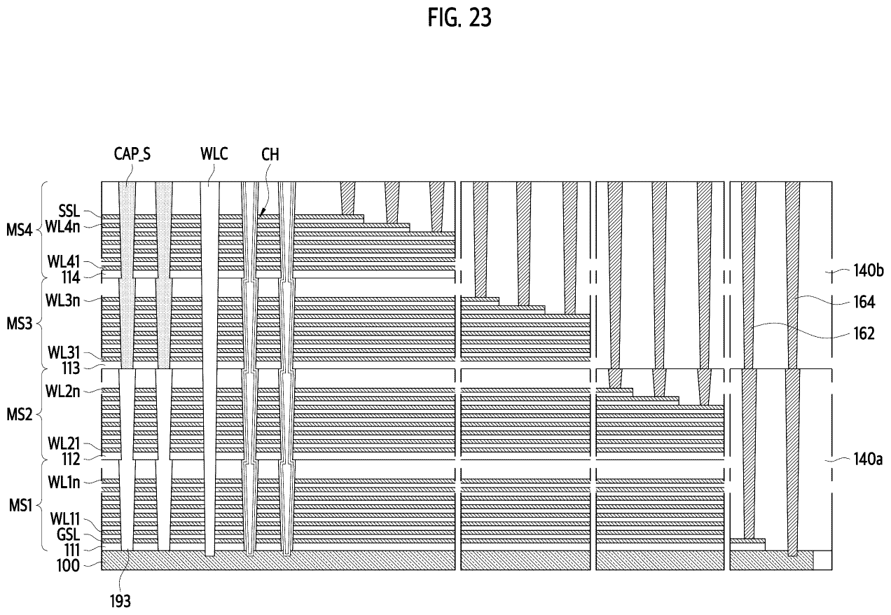

Referring to FIG. 23, the mold sacrificial film 120 (of FIG. 22) of the pre-first mold stack MS1p (of FIG. 22), the pre-second mold stack MS2p (of FIG. 22), the pre-third mold stack MS3p (of FIG. 22), and the pre-fourth mold stack MS4p (of FIG. 22) may be removed, and the plurality of gate electrodes GSL, WL11 to WL1n, WL21 to 2n, WL31 to WL3n, WL41 to 4n, and SSL may be formed. The mold sacrificial film 120 which is exposed in the gate cutting pattern hole WLC_H (of FIG. 22) may be removed and replaced with the plurality of gate electrodes GSL, WL11 to WL1n, WL21 to 2n, WL31 to WL3n, WL41 to 4n, and SSL.

Then, the gate cutting pattern WLC which fills the gate cutting pattern hole WLC_H (of FIG. 22) may be formed.

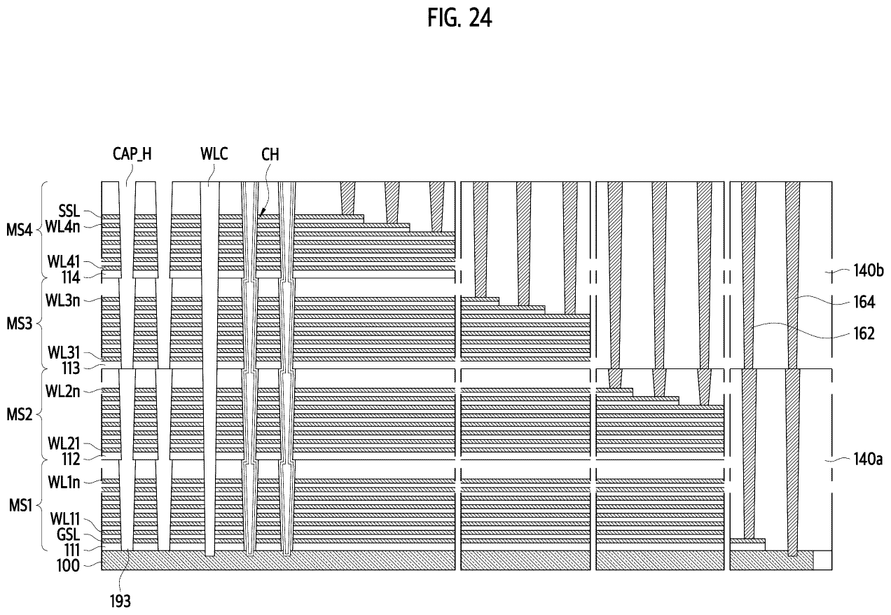

Referring to FIG. 24, the capacitor sacrificial film CAP_S (of FIG. 23) which penetrates the third mold stack MS3 and the fourth mold stack MS4 may be removed, so that the capacitor hole CAP_H may be formed. The cap filling insulation film 193 which penetrates the first mold stack MS1 and the second mold stack MS2 may be exposed in the capacitor hole CAP_H.

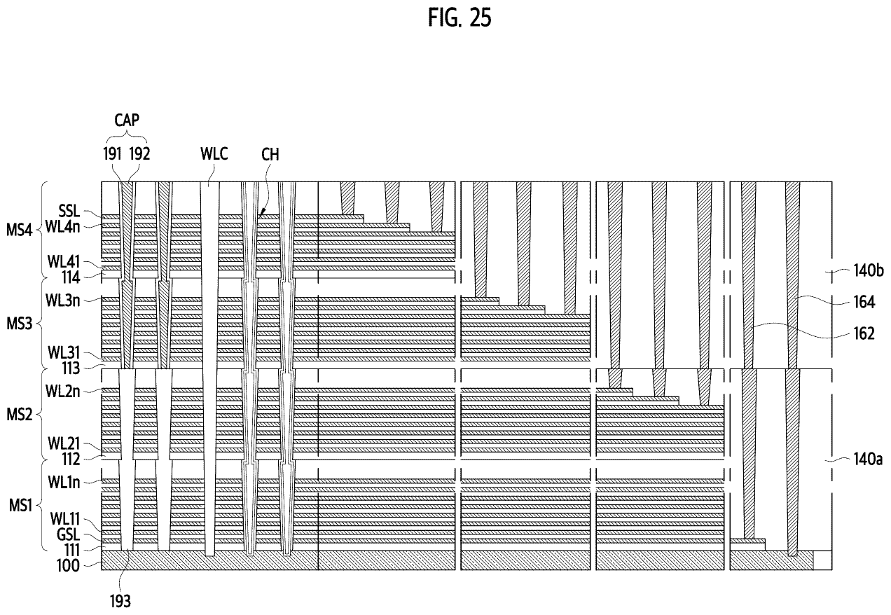

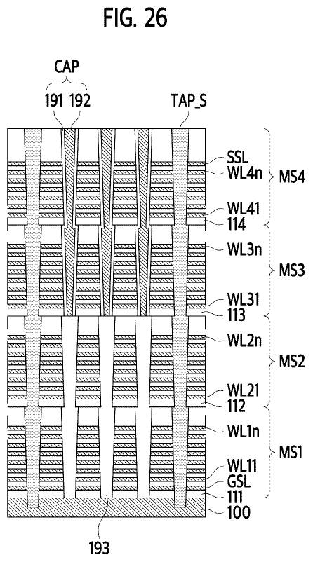

Referring to FIGS. 25 and 26, the capacitor structure CAP may be formed in the capacitor hole CAP_H (of FIG. 24). The dielectric film 191 and the electrode film 192 may be formed in the capacitor hole CAP_H (of FIG. 24) in sequential order.

According to some example embodiments, an electrode connection sacrificial film TAP_S spaced apart from the cap filling insulation film 193 and the capacitor structure CAP may be formed at the same time at which the capacitor sacrificial film CAP_S which penetrates the pre-first mold stack MS1p and the pre-second mold stack MS2p in FIGS. 13 and 14 and the capacitor sacrificial film CAP_S which penetrates the pre-third mold stack MS3p and the pre-fourth mold stack MS4p in FIG. 18 are formed.

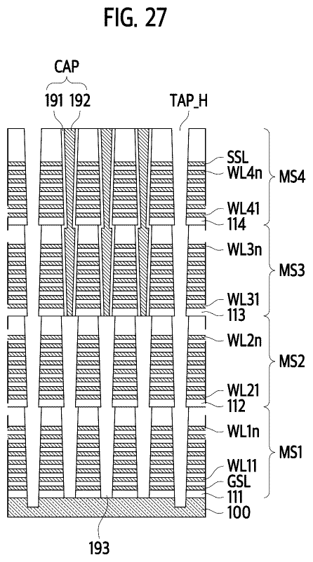

Referring to FIG. 27, the electrode connection sacrificial film TAP_S (of FIG. 26) may be removed, so that an electrode connection hole TAP_H may be formed. The plurality of gate electrodes GSL, WL11 to WL1n, WL21 to 2n, WL31 to WL3n, WL41 to 4n, and SSL of the first mold stack MS1 to the fourth mold stack MS4 may be exposed in the electrode connection hole TAP_H.

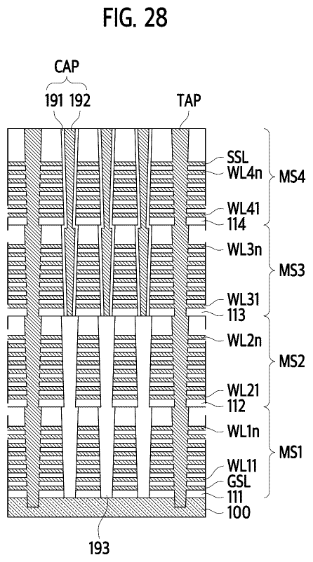

Referring to FIG. 28, the electrode connection structure TAP may be formed in the electrode connection hole TAP_H (of FIG. 27). The electrode connection structure TAP may be connected to the plurality of gate electrodes GSL, WL11 to WL1n, WL21 to 2n, WL31 to WL3n, WL41 to 4n, and SSL of the first mold stack MS1 to the fourth mold stack MS4.

Then, referring to FIGS. 4 and 8, above the fourth mold stack MS4, the bit line contact 182 and the bit line BL which are connected to the channel structure CH may be formed, and the cap connection contact 184 and the cap connection wiring 170 which are connected to the capacitor structure CAP may be formed. The contact via 186 and the cell wiring structure 180 which are connected to the cell contact 162 and the source contact 164 may be formed. The first bonding metal 195 which is connected to the bit line BL, the cap connection wiring 170, and the cell wiring structure 180 may be formed in the first inter-wiring insulation film 145, so that the cell structure CELL may be formed.

Then, the cell structure CELL may be bonded on the peripheral circuit structure PERI which includes the peripheral circuit element PT and the peripheral circuit wiring structure 260. The cell structure CELL may be bonded on the peripheral circuit structure PERI so that the first bonding metal 195 and the second bonding metal 295 are bonded.

Then, the third inter-layer insulation film 310 may be formed on the cell substrate 100, and the contact plug 166 which penetrates the first inter-layer insulation film 140a, the second inter-layer insulation film 140b, and the third inter-layer insulation film 310 may be formed. The input/output pad 320 and the capping insulation film 330 which are connected to the contact plug 166 may be formed. Unlike the cell contact 162 and the source contact 164, the contact plug 166 is illustrated as penetrating the first inter-layer insulation film 140a, the second inter-layer insulation film 140b, and the third inter-layer insulation film 310 at once, but it is merely an example. For example, when the first portion 162a of the cell contact and the first portion 164a of the source contact are formed, a portion of the contact plug 166 which penetrates the first inter-layer insulation film 140a may be formed, and when the second portion 162b of the cell contact and the second portion 164b of the source contact are formed, a portion of the contact plug 166 which penetrates the second inter-layer insulation film 140b may be formed.

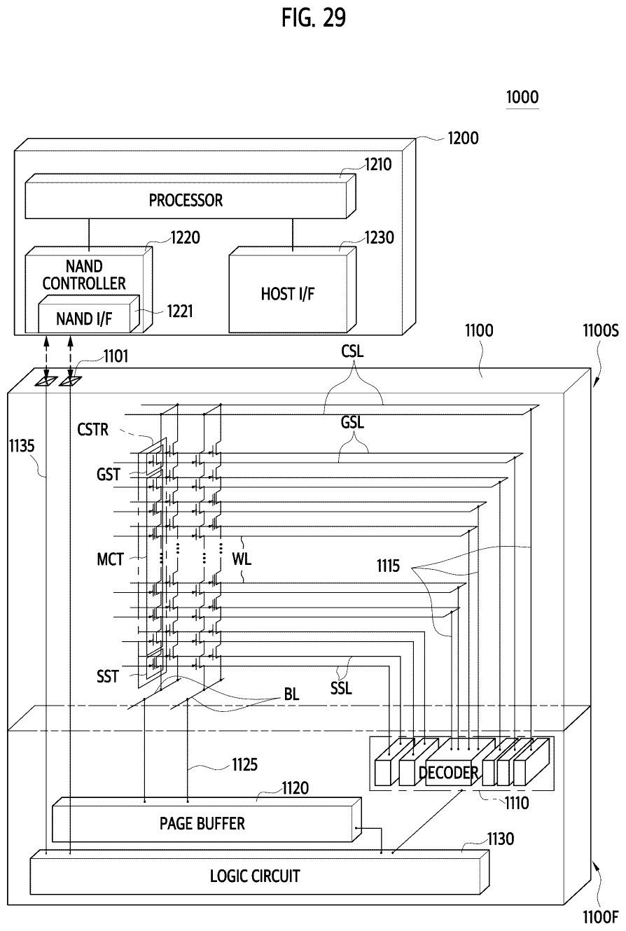

FIG. 29 is an example diagram for describing an electronic system including a semiconductor memory device according to some example embodiments.

Referring to FIG. 29, an electronic system 1000 according to some example embodiments may include a semiconductor memory device 1100 and a controller 1200 electrically connected to the semiconductor memory device 1100. The electronic system 1000 may be a storage device including one or a plurality of semiconductor memory devices 1100 or an electronic device including the storage device. For example, the electronic system 1000 may be a solid state drive device (SSD), a universal serial bus (USB), a computing system, a medical device, or a communication device including the one or the plurality of semiconductor memory devices 1100.

According to some example embodiments, the semiconductor memory device 1100 may be a non-volatile memory device (e.g., a NOT-AND (NAND) flash memory device) and may be, for example, the semiconductor memory device described above with reference to FIGS. 1 through 28. The semiconductor memory device 1100 may include a first structure 1100F and a second structure 1100S on the first structure 1100F.

According to some example embodiments, the first structure 1100F may be a peripheral circuit structure including a decoder circuit 1110 (e.g., the row decoder 33 of FIG. 1), a page buffer 1120 (e.g., the page buffer 35 of FIG. 1), and a logic circuit 1130 (e.g., the control logic 37 of FIG. 1). The first structure 1100F may correspond to, for example, the peripheral circuit structure PERI described with reference to FIGS. 1 through 28.

According to some example embodiments, the second structure 1100S may include the common source line CSL, the plurality of bit lines BL, and the plurality of cell strings CSTR described above with reference to FIG. 2. The cell strings CSTR may be connected to the decoder circuit 1110 through the word line WL, the at least one string selection line SSL, and the at least one ground selection line GSL. In addition, the cell strings CSTR may be connected to the page buffer 1120 through the bit lines BL. The second structure 1100S may correspond to, for example, the cell structure CELL described with reference to FIGS. 1 through 28.

According to some example embodiments, the common source line CSL and the cell strings CSTR may be electrically connected to the decoder circuit 1110 through first connection wirings 1115 extended from the first structure 1100F to the second structure 1100S. The bit lines BL may be electrically connected to the page buffer 1120 through second connection wirings 1125 extended from the first structure 1100F to the second structure 1100S.

According to some example embodiments, the semiconductor memory device 1100 may communicate with the controller 1200 through an input/output pad 1101 electrically connected to the logic circuit 1130 (e.g., the control logic 37 of FIG. 8). The input/output pad 1101 may be electrically connected to the logic circuit 1130 through an input/output connection wiring 1135 extended from an inside of the first structure 1100F to the second structure 1100S. The input/output pad 1101 may correspond to the input/output pad 320 described above with reference to FIG. 1 through 28. The input/output connection wiring 1135 may correspond to, for example, the contact plug 166 described above with reference to FIGS. 1 through 28.

According to some example embodiments, the controller 1200 may include a processor 1210 a NAND controller 1220, and a host interface 1230. In some example embodiments, the electronic system 1000 may include the plurality of semiconductor memory devices 1100, and in this case, the controller 1200 may control the plurality of semiconductor memory devices 1100.

According to some example embodiments, the processor 1210 may control an operation of a whole of the electronic system 1000, including the controller 1200. The processor 1210 may operate according to desired and/or alternatively predetermined firmware and access the semiconductor memory device 1100 by controlling the NAND controller 1220. The NAND controller 1220 may include a NAND interface 1221 processing communication with the semiconductor memory device 1100. A control instruction for controlling the semiconductor memory device 1100, data to record in the memory cell transistors MCT of the semiconductor memory device 1100, data to be read from the memory cell transistors MCT of the semiconductor memory device 1100, or the like may be transmitted. The host interface 1230 may provide a function for communication between the electronic system 1000 and an external host. When the control instruction is received from the external host through the host interface 1230, the processor 1210 may control the semiconductor memory device 1100 in response to the control instruction.

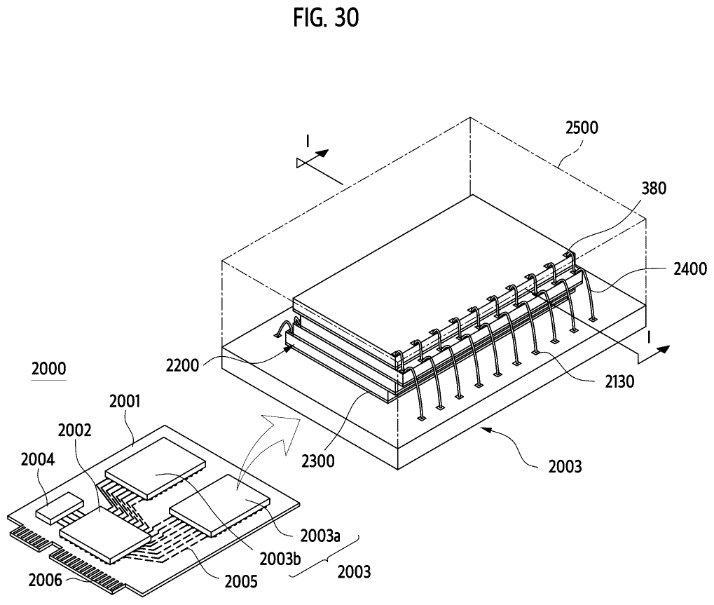

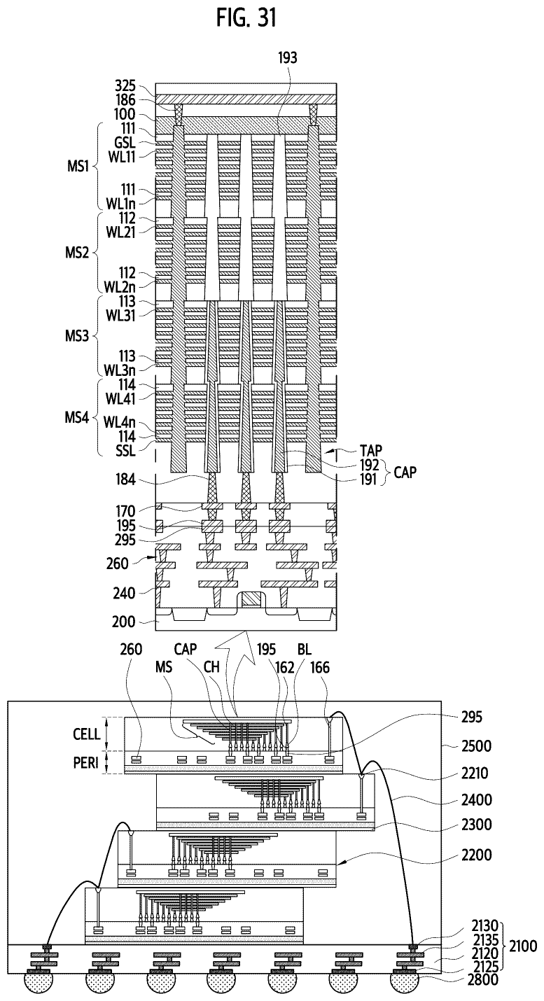

FIG. 30 is an example perspective diagram for describing an electronic system including a semiconductor memory device according to some example embodiments. FIG. 31 is an example diagram illustrating a cross section taken along line I-I of FIG. 30.

Referring to FIGS. 30 and 31, the electronic system according to some example embodiments may include a main substrate 2001, a main controller 2002 mounted to the main substrate 2001, one or more semiconductor packages 2003, and a dynamic random access memory (DRAM) 2004. A semiconductor package 2003 and the DRAM 2004 may be connected to the main controller 2002 by wiring patterns 2005 formed to the main substrate 2001.

According to some example embodiments, the main substrate 2001 may include a connector 2006 including a plurality of pins coupled to an external host. Disposition and the number of the plurality of pins in the connector 2006 may vary depending on a communication interface between an electronic system 2000 and the external host. In some example embodiments, the electronic system 2000 may communicate with the external host according to one of interfaces such as a universal serial bus (USB), a peripheral component interconnect express (PCI-Express), a serial advanced technology attachment (SATA), M-PHY for a universal flash storage (UFS). In some example embodiments, the electronic system 2000 may be operated by electric power supplied from the external host through the connector 2006. The electronic system 2000 may further include a power management integrated circuit (PMIC) that distributing the electric power supplied from the external host to the main controller 2002 and the semiconductor package 2003.

According to some example embodiments, the main controller 2002 may record data in the semiconductor package 2003 or read data from the semiconductor package 2003 and may improve an operation speed of the electronic system 2000.

According to some example embodiments, the DRAM 2004 may be a buffer memory for reducing a speed difference between the external host and the semiconductor package 2003 which is a data storage space. The DRAM 2004 included in the electronic system 2000 may operate also as a type of a cache memory and provide a space for temporarily storing data in a control operation for the semiconductor package 2003. When the DRAM 2004 is included in the electronic system 2000, the main controller 2002 may further include a DRAM controller for controlling the DRAM 2004 in addition to a NAND controller for controlling the semiconductor package 2003.

According to some example embodiments, the semiconductor package 2003 may include a first semiconductor package 2003a and a second semiconductor package 2003b disposed to be spaced apart from each other. Each of the first semiconductor package 2003a and the second semiconductor package 2003b may be a semiconductor package including a plurality of semiconductor chips 2200. Each of the first semiconductor package 2003a and the second semiconductor package 2003b may include a package substrate 2100, the semiconductor chips 2200 on the package substrate 2100, adhesive layers 2300 disposed to respective lower surfaces of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

According to some example embodiments, the package substrate 2100 may be a printed circuit board including package upper pads 2130. Each of the semiconductor chips 2200 may include an input/output pad 2210. The input/output pad 2210 may correspond to the input/output pad 1101 of FIG. 29.

According to some example embodiments, the connection structure 2400 may be a bonding wire that electrically connects the input/output pad 2210 and the package upper pads 2130. Thus, in each of the first semiconductor package 2003a and the second semiconductor package 2003b, the semiconductor chips 2200 may be electrically connected to each other with a bonding wire scheme and may be electrically connected to the package upper pads 2130 of the package substrate 2100. In some example embodiments, in each of the first semiconductor package 2003a and the second semiconductor package 2003b, the semiconductor chips 2200 may be electrically connected to each other by a connection structure including a through-silicon via TSV, instead of the connection structure 2400 in the bonding wire scheme.

According to some example embodiments, the main controller 2002 and the semiconductor chips 2200 may be included in one package. In some example embodiments, the main controller 2002 and the semiconductor chips 2200 may be mounted to an interposer substrate different from the main substrate 2001, and the main controller 2002 and the semiconductor chips 2200 may be connected to each other by a wiring formed to the interposer substrate.

According to some example embodiments, the package substrate 2100 may be a printed circuit board. The package substrate 2100 may include a package substrate body portion 2120, the package upper pads 2130 which are disposed on an upper surface of the package substrate body portion 2120, lower pads 2125 disposed on a lower surface of the package substrate body portion 2120 or exposed through the lower surface, and internal wirings 2135 electrically connecting the upper pads 2130 and the lower pads 2125 in the package substrate body portion 2120. The upper pads 2130 may be electrically connected to connection structures 2400. The lower pads 2125 may be connected to the wiring patterns 2005 of the main substrate 2001 of the electronic system 2000 through conductive connection parts 2800 as illustrated in FIG. 30.

In the electronic system 2000 according to some example embodiments, each of the semiconductor chips 2200 may include the semiconductor memory device described above with reference to FIGS. 1 through 28. For example, the semiconductor chips 2200 may include the capacitor structure CAP and the cap filling insulation film 193. The capacitor structure CAP and the cap filling insulation film 193 may vertically overlap each other.

In the electronic system 2000 according to some example embodiments, when a signal is input to or output from the semiconductor memory device of the semiconductor chips 2200, noise in the input or output signal may be reduced by using the capacitor structure CAP.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The various example embodiments of the present disclosure have been described above in detail, but the scope of the present disclosure is not limited thereto. It will be apparent to those skilled in the art that various changes and modifications may be allowed within the range of the technical spirit of the present disclosure. In addition, the above-described example embodiments may be implemented without a portion of elements thereof, and each of the example embodiments may be implemented in combination with another.

What is claimed is:

1. A semiconductor memory device comprising:
a mold structure comprising a plurality of gate electrodes stacked in a first direction, the mold structure including a first mold portion and a second mold portion that are disposed in the first direction, the mold structure including a capacitor hole penetrating the mold structure in the first direction;
a capacitor structure in the capacitor hole and penetrating a portion of the mold structure in the first direction, the capacitor structure including a dielectric film and an electrode film; and
a cap filling insulation film in the capacitor hole, the cap filling insulation film penetrating at least a part of the mold structure in the first direction and overlapping the capacitor structure in the first direction, wherein
the capacitor hole includes a first hole portion in the first mold portion and a second hole portion in the second mold portion,
the first hole portion does not penetrate the second mold portion,
the second hole portion connected to the first hole portion and does not penetrate the second mold portion, and
the dielectric film extends along the first hole portion and does not extend along the second hole portion.

2. The semiconductor memory device of claim 1, wherein
a first surface of the mold structure is opposite a second surface of the mold structure,
the capacitor structure penetrates the first surface of the mold structure, and
the cap filling insulation film penetrates the second surface of the mold structure.

3. The semiconductor memory device of claim 1, wherein
the plurality of gate electrodes comprises a plurality of first gate electrodes stacked in the first direction and a plurality of second gate electrodes stacked in the first direction on the plurality of first gate electrodes,
the first mold portion comprises a first mold stack comprising the plurality of first gate electrodes,
the second mold portion comprises a second mold stack disposed in the first direction with the first mold stack and comprising the plurality of second gate electrodes,
the capacitor structure penetrates the first mold stack, and
the cap filling insulation film penetrates the second mold stack.

4. The semiconductor memory device of claim 3, wherein the capacitor structure and the cap filling insulation film have a step at a boundary between the first mold stack and the second mold stack.

5. The semiconductor memory device of claim 3, wherein the electrode film is in contact with the cap filling insulation film at a boundary between the first mold stack and the second mold stack.

6. The semiconductor memory device of claim 3, wherein
the dielectric film is between the electrode film and the cap filling insulation film in the first direction at a boundary between the first mold stack and the second mold stack, and
the electrode film is spaced apart from the cap filling insulation film.

7. The semiconductor memory device of claim 1, further comprising:
a gate cutting pattern penetrating the mold structure in the first direction and dividing the mold structure into a first block and a second block; and
a channel structure penetrating the mold structure in the first direction in the second block, wherein
the capacitor structure and the cap filling insulation film penetrate the mold structure in the first block.

8. The semiconductor memory device of claim 7, further comprising
a bit line on the mold structure in the first direction and connected to the channel structure,
wherein the cap filling insulation film is closer to the bit line in the first direction compared to the capacitor structure.

9. The semiconductor memory device of claim 8, further comprising:
a cap connection wiring connected to the capacitor structure,
wherein the cap connection wiring and the bit line are on opposite sides of the mold structure in the first direction.

10. The semiconductor memory device of claim 7, wherein, in a direction crossing the first direction, a maximum width of the channel structure and a maximum width of the capacitor structure are equal.

11. The semiconductor memory device of claim 1, wherein, in the first direction, a height of the capacitor structure and a height of the cap filling insulation film are different.

12. The semiconductor memory device of claim 1, further comprising:
an electrode connection structure penetrating the mold structure in the first direction, wherein the electrode connection structure is connected to the plurality of gate electrodes.

13. A semiconductor memory device comprising:
a mold structure including a plurality of mold stacks, the plurality of mold stacks each including a plurality of gate electrodes stacked in a first direction, a first surface of the mold structure being opposite a second surface of the mold structure in the first direction;
a capacitor structure penetrating at least one of the mold stacks in the first direction from the first surface of the mold structure;
a cap filling insulation film penetrating the at least one of the mold stacks in the first direction from the second surface of the mold structure, and the cap filling insulation film being connected to the capacitor structure in the first direction; and
a channel structure penetrating the mold structure in the first direction,
wherein the capacitor structure and the cap filling insulation film do not overlap in a direction crossing the first direction.

14. The semiconductor memory device of claim 13, further comprising:
a gate cutting pattern configured penetrating the mold structure in the first direction, wherein
the gate cutting pattern is between the capacitor structure and the channel structure.

15. The semiconductor memory device of claim 13, further comprising:
a bit line on the first surface of the mold structure and connected to the channel structure; and
a cap connection wiring at a same height level as the bit line in the first direction, the cap connection wiring being connected to the capacitor structure.

16. The semiconductor memory device of claim 13, wherein
the capacitor structure comprises an electrode film and a dielectric film,
the electrode film extends in the first direction, and
the dielectric film surrounds the electrode film.

17. The semiconductor memory device of claim 13, wherein, in a direction crossing the first direction, a width of a first bonding surface of the capacitor structure in contact with the cap filling insulation film and a width of a second bonding surface of the cap filling insulation film in contact with the capacitor structure are different.

18. The semiconductor memory device of claim 13, wherein, in the first direction, a height of the capacitor structure and a height of the cap filling insulation film are equal.

19. The semiconductor memory device of claim 13, wherein the channel structure has a step at a boundary between the plurality of mold stacks.

20. A semiconductor memory device comprising:
a mold structure including a plurality gate electrodes stacked in a first direction, the mold structure including a first mold portion and a second mold portion that are disposed in the first direction;
an inter-layer insulation film covering the mold structure;
a capacitor structure penetrating the first mold portion in the first direction, the capacitor structure including a dielectric film and an electrode film;
a cap filling insulation film penetrating the second mold portion in the first direction and overlapping the capacitor structure in the first direction;
a contact plug penetrating the inter-layer insulation film, the contact plug being electrically connected to the capacitor structure; and
an input/output pad on the inter-layer insulation film and connected to the contact plug,
wherein the capacitor structure does not overlap the second mold portion in a direction crossing the first direction, and
the cap filling insulation film does not overlap the first mold portion in the direction crossing the first direction.
